(19) United States
(12) Patent Application Publication
(10) Pub. No.: US 2023/0162348 A1
(43) Pub. Date: May 25, 2023

(54) STORAGE MEDIUM, INFORMATION PROCESSING APPARATUS, AND INSPECTION METHOD

(71) Applicant: FUJITSU LIMITED, Kawasaki-shi (JP)

(72) Inventors: Atsunori Moteki, Inagi (JP); Tomohiro AOYAGI, Toshima (JP); Ayu Karasudani, Yamato (JP); Toshiyuki Yoshitake, Kawasaki (JP); Kensuke KURAKI, Ichikawa (JP); Katsuhisa Nakazato, Kawasaki (JP)

(73) Assignee: FUJITSU LIMITED, Kawasaki-shi (JP)

(21) Appl. No.: 18/152,652

(22) Filed: Jan. 10, 2023

Related U.S. Application Data
(63) Continuation of application No. PCT/JP2021/015291, filed on Apr. 13, 2021.

(30) Foreign Application Priority Data
Jul. 29, 2020 (JP) 2020-128279

(51) Int. Cl. G06T 7/00; G06T 7/90; G06F 30/10

(52) U.S. Cl. CPC G06T 7/001; G06T 7/90; G06F 30/10; G06T 2200/04; G06T 2207/10024; G06T 2207/30108

(57) ABSTRACT

A non-transitory computer-readable storage medium storing an inspection program that causes at least one computer to execute a process, the process includes acquiring a captured image that includes an inspection object to which a jig that provides a feature line that has a certain positional relationship with the inspection object is coupled; acquiring a three-dimensional image in a state where the jig is coupled to the inspection object; detecting a plurality of feature lines from the captured image; and displaying the three-dimensional image superimposed on the inspection object which is included in the captured image and to which the jig is coupled, by using the plurality of feature lines detected from the captured image and line segments of the three-dimensional image which correspond to the plurality of feature lines.

### CROSS-REFERENCE TO RELATED APPLICATION

This application is a continuation application of International Application PCT/JP2021/015291 filed on Apr. 13, 2021 and designated the U.S., the entire contents of which are incorporated herein by reference. The International Application PCT/JP2021/015291 is based upon and claims the benefit of priority of the prior Japanese Patent Application No. 2020-128279, filed on Jul. 29, 2020, the entire contents of which are incorporated herein by reference.

### FIELD

The present invention relates to an inspection program, an information processing apparatus, and an inspection method.

### BACKGROUND

As an inspection technique for inspecting various members manufactured in a manufacturing place and a structure or the like assembled with various members, for example, a technique for imaging an inspection object and superimposing and displaying three-dimensional CAD data (three-dimensional image) as the inspection object, using the augmented reality technique (AR technique) has been known. According to the inspection technique, it is possible to inspect errors such as a dimension and an angle by measuring a deviation amount between the inspection object and the three-dimensional CAD data or the like.

Patent Document 1: Japanese Laid-open Patent Publication No. 2017-091078, Patent Document 2: Japanese Laid-open Patent Publication No. 2020-003995.

### SUMMARY

According to an aspect of the embodiments, a non-transitory computer-readable storage medium storing an inspection program that causes at least one computer to execute a process, the process includes acquiring a captured image that includes an inspection object to which a jig that provides a feature line that has a certain positional relationship with the inspection object is coupled; acquiring a three-dimensional image in a state where the jig is coupled to the inspection object; detecting a plurality of feature lines from the captured image; and displaying the three-dimensional image superimposed on the inspection object which is included in the captured image and to which the jig is coupled, by using the plurality of feature lines detected from the captured image and line segments of the three-dimensional image which correspond to the plurality of feature lines.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an application example of an information processing apparatus;

FIG. 2 is a diagram illustrating an example of a hardware configuration of the information processing apparatus;

FIG. 3 is a first diagram illustrating an example of a functional configuration of the information processing apparatus;

FIG. 4 is a first diagram illustrating a coupling example in a case where an inspection jig is coupled to an inspection object and an edge line detection example;

FIG. 5 is a first diagram illustrating a specific example of coupled three-dimensional CAD data and an identification example of line segments;

FIG. 6A is first diagrams illustrating examples of an inspection screen;

FIG. 6B is second diagrams illustrating examples of the inspection screen;

FIG. 7 is a first flowchart illustrating a flow of inspection processing;

FIG. 8 is a view illustrating an example of the inspection jig suitable for a two-hole inspection object;

FIG. 9 is a view illustrating an example of the inspection jig suitable for a one-hole inspection object;

FIG. 10 is a view illustrating an example of the inspection jig suitable for a non-hole inspection object;

FIG. 11 is a second flowchart illustrating a flow of inspection processing;

FIG. 12 is schematic views for describing a relationship between superimposed display and deviation information;

FIG. 13 is a view and tables illustrating an example of a shape of the inspection jig and color arrangement data of the jig;

FIG. 14 is a second diagram illustrating an example of the functional configuration of the information processing apparatus;

FIG. 15 is a second diagram illustrating a coupling example in the case where the inspection jig is coupled to the inspection object and an edge line detection example;

FIG. 16 is a second diagram illustrating a specific example of the coupled three-dimensional CAD data and an identification example of line segments;

FIG. 17 is a first diagram illustrating a specific example of corresponding pair determination processing;

FIG. 18A and FIG. 18B are second diagrams illustrating a specific example of the corresponding pair determination processing;

FIG. 19 is a third diagram illustrating a specific example of the corresponding pair determination processing;

FIG. 20 is third diagrams illustrating examples of an inspection screen; and

FIG. 21 is a third flowchart illustrating a flow of inspection processing.

### DESCRIPTION OF EMBODIMENTS

Here, to superimpose and display the three-dimensional CAD data by the AR technique, it is needed to detect appropriate feature lines (for example, feature lines that are three-dimensionally distributed and have a sufficient length) from a captured image including the inspection object.

However, there may be a situation where the appropriate feature lines are not able to be detected and the three-dimensional CAD data is not able to be superimposed and displayed depending on a shape and an imaging environment of the inspection object.

In one aspect, an inspection program, an information processing apparatus, and an inspection method are provided that superimpose and display a three-dimensional image on an inspection object included in a captured image and inspect the inspection object.

An inspection program, an information processing apparatus, and an inspection method that superimpose and display a three-dimensional image on an inspection object included in a captured image and inspect the inspection object can be provided.

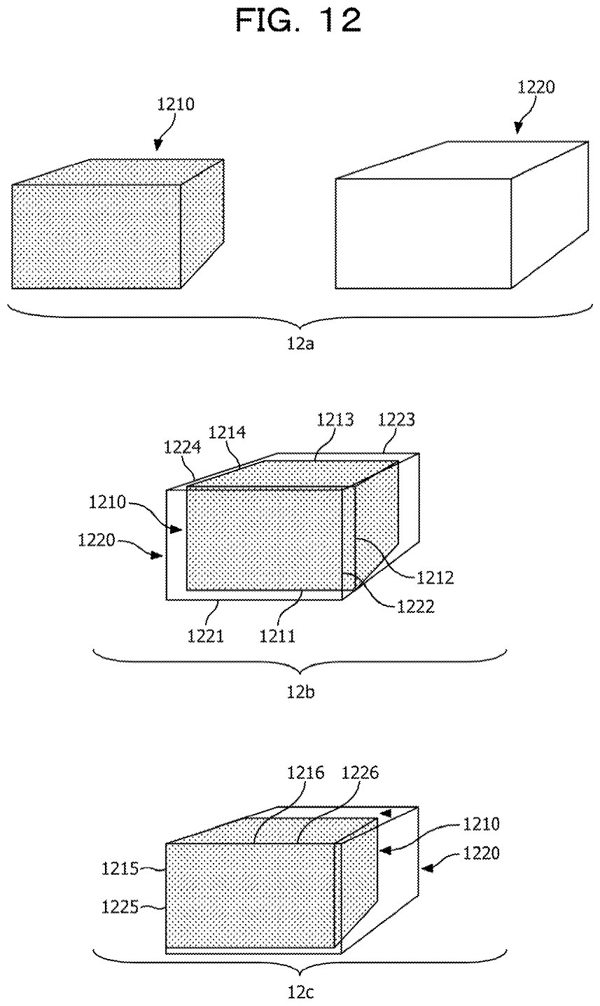

First, a relationship between superimposed display of an inspection object and three-dimensional CAD data performed by an information processing apparatus according to each embodiment below and deviation information indicating a deviation amount between the inspection object and the three-dimensional CAD data or the like will be briefly described with reference to FIGS. 12A to 12C.

FIG. 12 is schematic views for describing the relationship between the superimposed display and the deviation information. Note that, the superimposed display here indicates to superimpose and display a three-dimensional image that is structural data (for example, three-dimensional CAD data) of an inspection object on a captured image of the inspection object.

As illustrated in 12a of FIG. 12, in a case where a three-dimensional image 1220 that is three-dimensional CAD data of an inspection object is superimposed and displayed on an inspection object 1210 included in a captured image, any superimposition method is generally allowed.

Of these, 12b of FIG. 12 illustrates a case where four pairs are specified from among “the plurality of pairs” including:
a plurality of edge lines (an example of feature lines) detected from the captured image including the inspection object 1210; and
a plurality of line segments forming the three-dimensional image 1220 of the inspection object (a line segment corresponding to an edge line), and are superimposed and displayed (because superimposed display needs four pairs in principle).

Specifically, 12b of FIG. 12 illustrates a superimposition method of specifying, as four pairs:
an edge line 1211 of the inspection object 1210 included in the captured image and a line segment 1221 forming the three-dimensional image 1220;
an edge line 1212 of the inspection object 1210 included in the captured image and a line segment 1222 forming the three-dimensional image 1220;
an edge line 1213 of the inspection object 1210 included in the captured image and a line segment 1223 forming the three-dimensional image 1220; and
an edge line 1214 of the inspection object 1210 included in the captured image and a line segment 1224 forming the three-dimensional image 1220, and superimposing and displaying the line segments so as to minimize a sum of respective deviation amounts of the specified four pairs.

In the case of the superimposition method illustrated in 12b of FIG. 12, each of the four pairs between the inspection object 1210 and the three-dimensional image 1220 included in the captured image has a deviation.

Therefore, an inspector can easily recognize that the inspection object 1210 and the three-dimensional image 1220 deviate from each other as the deviation information. However, it is not possible for the inspector to recognize a cause of the deviation, for example, which part of the inspection object 1210 has a defect that causes the deviation, as the deviation information.

In contrast, the information processing apparatus according to each embodiment below specifies a reference line (one of edge lines) or a reference point (a point on the edge line) defined by a manufacturer for the inspection object 1210 and performs superimposed display so that the reference line (or the reference point) is matched.

12c of FIG. 12 illustrates a case where reference lines 1215 and 1216 are specified from the edge line of the inspection object 1210 included in the captured image and line segments 1225 and 1226 corresponding to the reference lines are specified from the line segments forming the three-dimensional image 1220, and superimposed display is performed so that the reference lines match the line segments.

In this way, in the case where superimposed display is performed so that the reference line is matched, the inspector compares the edge line of the inspection object 1210 other than the reference line and the line segment corresponding to the edge line other than the reference line among the line segments forming the three-dimensional image 1220 other than the reference line. As a result, the inspector can recognize the deviation amount, the cause of the deviation in addition to whether or not the deviation occurs, as the deviation information.

Hereinafter, each embodiment will be described with reference to the accompanying drawings. However, in this specification and the drawings regarding each embodiment below, components having substantially the same functional configuration are denoted by the same reference numerals, and redundant description is omitted.

### First Embodiment

<Application Example of Information Processing Apparatus>

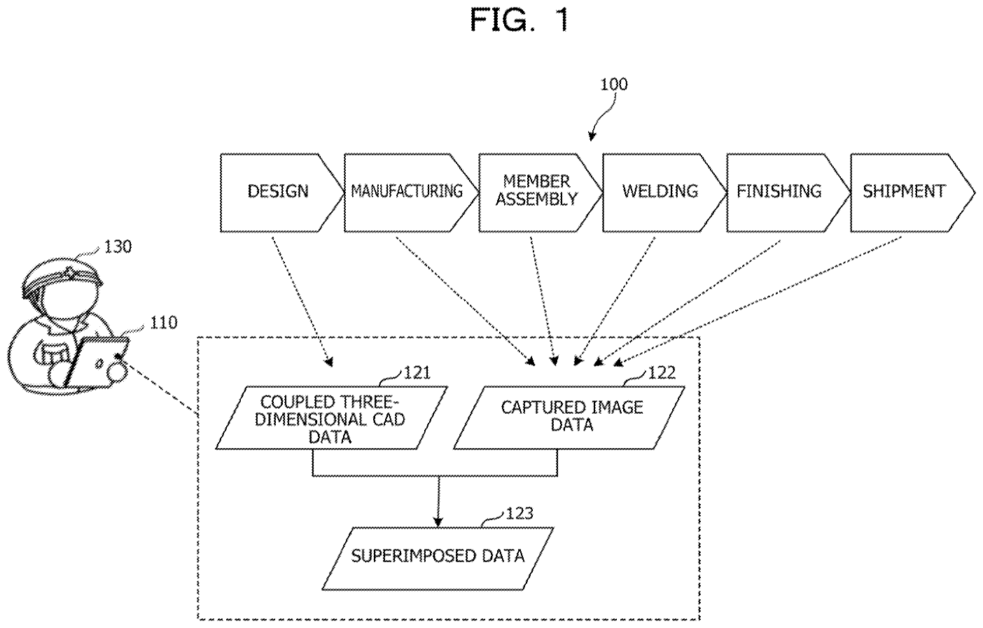

First, an application example of an information processing apparatus according to a first embodiment will be described. FIG. 1 is a diagram illustrating the application example of the information processing apparatus. In FIG. 1, a process 100 illustrates a general process from manufacturing a product by a manufacturer or the like to shipping the product.

As illustrated in FIG. 1, the manufacturer or the like first designs the product in a design process and generates three-dimensional CAD data. At this time, it is assumed that the manufacturer or the like design an inspection jig and also generate three-dimensional CAD data of the jig.

Subsequently, the manufacturer or the like manufactures various members included in the product based on the three-dimensional CAD data in a manufacturing process and assembles the manufactured various members and generate a structure in a member assembly process. Subsequently, the manufacturer welds the structures with each other in a welding process and executes finishing processing in a finishing process, and thereby, completes the product. Thereafter, the manufacturer or the like ships the completed product in a shipping process.

Here, an information processing apparatus (for example, a tablet terminal) 110 according to the first embodiment acquires captured image data obtained by imaging an inspection object (various members, structure, or the like) in each process that is captured image data 122 including an “inspection object to which an inspection jig is coupled”. Furthermore, the information processing apparatus 110 according to the first embodiment displays superimposed data 123 in which corresponding coupled three-dimensional CAD data 121 is superposed on the acquired captured image data 122 to an inspector 130.

The coupled three-dimensional CAD data here is three-dimensional CAD data (a three-dimensional image) of a state where the inspection jig is coupled to the inspection object and is generated based on three-dimensional CAD data of the inspection jig and three-dimensional CAD data of the inspection object.

As a result, the inspector 130 can inspect whether or not the inspection object in each process matches design content.

<Hardware Configuration of Information Processing Apparatus>

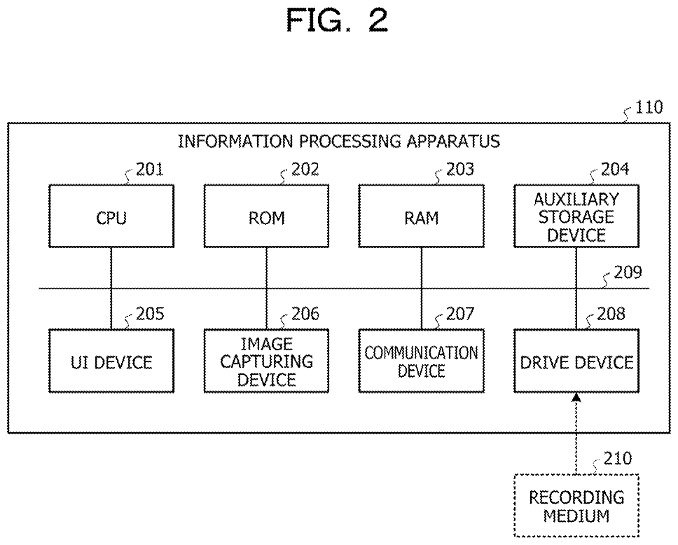

Next, a hardware configuration of the information processing apparatus 110 will be described. FIG. 2 is a diagram illustrating an example of the hardware configuration of the information processing apparatus. As illustrated in FIG. 2, the information processing apparatus 110 includes a central processing unit (CPU) 201, a read only memory (ROM) 202, and a random access memory (RAM) 203. The CPU 201, the ROM 202, and the RAM 203 form a so-called computer.

Furthermore, the information processing apparatus 110 includes an auxiliary storage device 204, a UI device 205, an image capturing device 206, a communication device 207, and a drive device 208. Note that individual pieces of hardware of the information processing apparatus 110 are connected to each other via a bus 209.

The CPU 201 is a device that executes various programs (for example, an inspection program to be described below or the like) installed in the auxiliary storage device 204.

The ROM 202 is a nonvolatile memory. The ROM 202 functions as a main storage device that stores various programs, data, and the like needed for the CPU 201 to execute the various programs installed in the auxiliary storage device 204. Specifically, the ROM 202 functions as a main storage device that stores, for example, a boot program such as a basic input/output system (BIOS) or an extensible firmware interface (EFI).

The RAM 203 is a volatile memory such as a dynamic random access memory (DRAM) or a static random access memory (SRAM). The RAM 203 functions as a main storage device that provides a work area expanded when the various programs installed in the auxiliary storage device 204 are executed by the CPU 201.

The auxiliary storage device 204 is an auxiliary storage device that stores various programs and information used when the various programs are executed. For example, a three-dimensional CAD data storage unit (to be described below) that stores coupled three-dimensional CAD data 121 or the like is implemented by the auxiliary storage device 204.

The UI device 205 provides the inspector 130 with an inspection screen to display the coupled three-dimensional CAD data 121, the captured image data 122, and the superimposed data 123. Furthermore, the UI device 205 receives various instructions from the inspector 130 via the inspection screen.

The image capturing device 206 is an imaging device that images the inspection object to which the inspection jig is coupled in each process and generates the captured image data 122. The communication device 207 is a communication device that is connected to a network and performs communication.

The drive device 208 is a device to which a recording medium 210 is set. The recording medium 210 mentioned here includes a medium that optically, electrically, or magnetically records information, such as a compact disc read only memory (CD-ROM), a flexible disk, or a magneto-optical disk. Alternatively, the recording medium 210 may include a semiconductor memory or the like that electrically records information, such as a ROM or a flash memory.

Note that the various programs to be installed in the auxiliary storage device 204 are installed, for example, when the distributed recording medium 210 is set to the drive device 208, and the various programs recorded in the recording medium 210 are read by the drive device 208. Alternatively, the various programs to be installed in the auxiliary storage device 204 may be installed by being downloaded from a network via the communication device 207.

<Functional Configuration of Information Processing Apparatus>

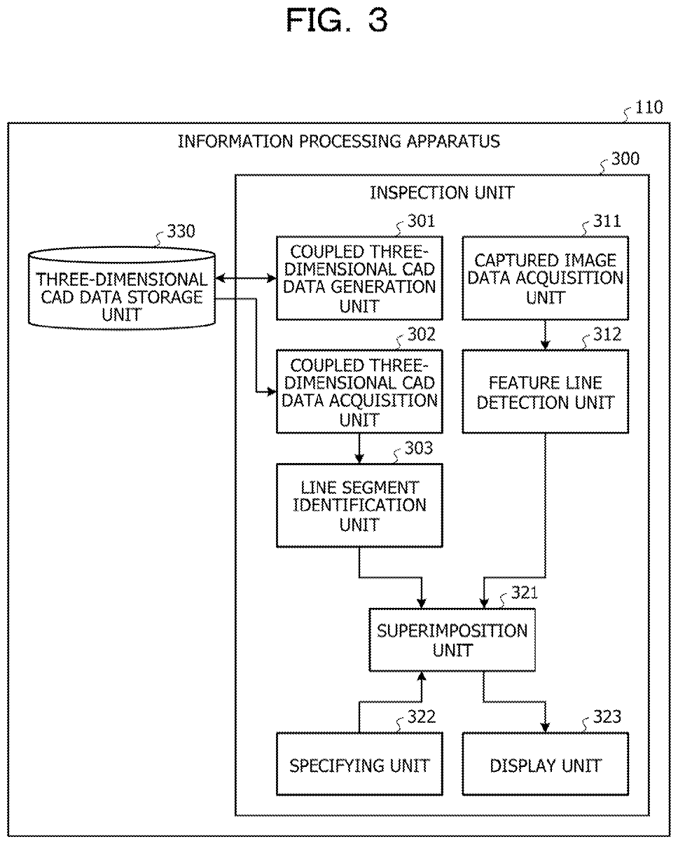

Next, a functional configuration of the information processing apparatus 110 will be described. FIG. 3 is a first diagram illustrating an example of a functional configuration of the information processing apparatus. As described above, the inspection program is installed in the information processing apparatus 110, and the information processing apparatus 110 functions as an inspection unit 300 by executing the program.

The inspection unit 300 includes a coupled three-dimensional CAD data generation unit 301, a coupled three-dimensional CAD data acquisition unit 302, a line segment identification unit 303, a captured image data acquisition unit 311, a feature line detection unit 312, a superimposition unit 321, a specifying unit 322, and a display unit 323.

The coupled three-dimensional CAD data generation unit 301 reads three-dimensional CAD data of the inspection jig and three-dimensional CAD data of the inspection object stored in a three-dimensional CAD data storage unit 330 in advance. Furthermore, the coupled three-dimensional CAD data generation unit 301 generates three-dimensional CAD data of a state where the inspection jig is coupled to the inspection object based on the read three-dimensional CAD data and stores the generated data in the three-dimensional CAD data storage unit 330 as coupled three-dimensional CAD data.

The coupled three-dimensional CAD data acquisition unit 302 is an example of a second acquisition unit and reads the coupled three-dimensional CAD data 121 (coupled three-dimensional CAD data corresponding to the inspection object to which the inspection jig is coupled) specified by the inspector 130 from the three-dimensional CAD data storage unit 330.

The line segment identification unit 303 identifies each line segment in the read coupled three-dimensional CAD data 121. Moreover, the line segment identification unit 303 notifies the superimposition unit 321 of the read coupled three-dimensional CAD data (including information regarding each identified line segment).

The captured image data acquisition unit 311 is an example of a first acquisition unit and images the inspection object to which the inspection jig is coupled in each process by controlling the image capturing device 206 based on an instruction of the inspector 130 and acquires the captured image data 122.

The feature line detection unit 312 is an example of a detection unit and detects an edge line from the captured image data 122. Specifically, the feature line detection unit 312 detects an edge line of the inspection object to which the inspection jig is coupled, the inspection object being included in the captured image data. Furthermore, the feature line detection unit 312 notifies the superimposition unit 321 of the acquired captured image data 122 (including information regarding the detected edge line).

The superimposition unit 321 notifies the display unit 323 of the notified coupled three-dimensional CAD data 121 and captured image data 122 so as to display the coupled three-dimensional CAD data 121 and the captured image data 122 to the inspector 130 via the UI device 205.

Furthermore, in response to the display of the coupled three-dimensional CAD data 121 and the captured image data 122 via the UI device 205, the superimposition unit 321 receives notifications regarding
specification of a reference line in the captured image data 122 and specification of a line segment in the coupled three-dimensional CAD data corresponding to the reference line and
specification of an edge line other than the reference line in the captured image data 122 and specification of a line segment in the coupled three-dimensional CAD data corresponding to the edge line, from the specifying unit 322. Note that the reference line indicates an edge line, to be a reference, defined by a manufacturer for the inspection object in each process.

Furthermore, the superimposition unit 321 estimates the position and posture of the image capturing device 206 based on the specification of the reference line, the specification of the corresponding line segment, the specification of the edge line other than the reference line, and the specification of the corresponding line segment. Furthermore, the superimposition unit 321 scales, moves, or rotates the coupled three-dimensional CAD data based on the estimated position and posture of the image capturing device 206 and superimposes the coupled three-dimensional CAD data on the captured image data 122 to generate superimposed data 123. Moreover, the superimposition unit 321 notifies the display unit 323 of the generated superimposed data 123.

In a case where the inspector 130 specifies the reference line, the corresponding line segment, the edge line other than the reference line, and the corresponding line segment, the specifying unit 322 notifies the superimposition unit 321 of the specified lines and line segments in response to the specification.

The display unit 323 generates and displays an inspection screen that displays the coupled three-dimensional CAD data 121, the captured image data 122, and the superimposed data 123 that have been notified from the superimposition unit 321. Note that it is assumed that the inspection screen generated by the display unit 323 include operation buttons used to specify the reference line, the corresponding line segment, the edge line other than the reference line, and the corresponding line segment.

<Coupling Example in a Case Where Inspection Jig Is Coupled to Inspection Object and Edge Line Detection Example>

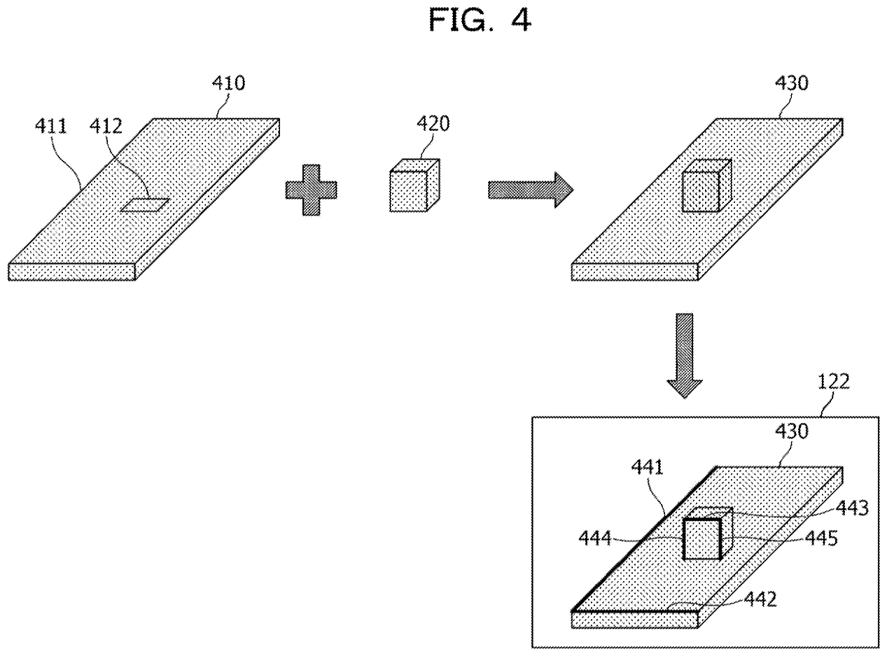

Next, a coupling example in a case where the inspection jig is coupled to the inspection object and a detection example of an edge line detected from the captured image data 122 including the inspection object to which the inspection jig is coupled, will be described. FIG. 4 is a first diagram illustrating the coupling example in a case where the inspection jig is coupled to the inspection object and the edge line detection example.

As illustrated in FIG. 4, for an inspection object 410, a manufacturer defines a reference line 411 and a position 412 at which an inspection jig 420 is coupled (lines corresponding to a shape of the inspection jig 420, four sides of a rectangle in the example in FIG. 4).

Furthermore, as illustrated in FIG. 4, the inspection jig 420 has a rectangular parallelepiped shape and provides an edge line having a predetermined positional relationship with the reference line 411 of the inspection object 410 when being coupled to the inspection object 410. Specifically, the inspection jig 420 provides
edge lines that are independent of each other and have a sufficient length and
an edge line that is substantially orthogonal to a plane to which the reference line 411 belongs (that is, an edge line that is three-dimensionally distributed with respect to the reference line 411) in a case where the inspection jig 420 is coupled to the inspection object 410.

However, the shape of the inspection jig 420 is not limited to the rectangular parallelepiped shape and may be a shape other than the rectangular parallelepiped shape as long as the inspection jig 420 can provide the edge lines described above.

Furthermore, as illustrated in FIG. 4, when an inspection object 430 after the inspection jig 420 is coupled to the inspection object 410 at the position 412 is imaged by the image capturing device 206, the captured image data acquisition unit 311 acquires the captured image data 122.

Moreover, as illustrated in FIG. 4, the feature line detection unit 312 detects edge lines 441 to 445 and the like of the inspection object 430 included in the captured image data 122.

<Specific Example of Coupled Three-Dimensional CAD Data and Identification Example of Line Segment>

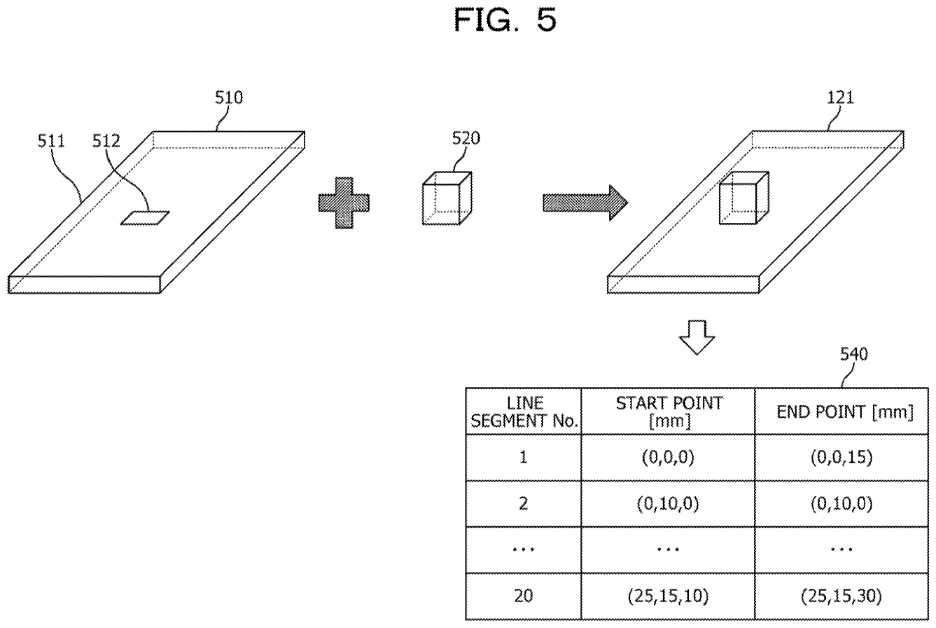

Next, a specific example of the coupled three-dimensional CAD data and an identification example of a line segment forming the coupled three-dimensional CAD data will be described. FIG. 5 is a first diagram illustrating the specific example of the coupled three-dimensional CAD data and the identification example of the line segment.

In FIG. 5, three-dimensional CAD data 510 is three-dimensional CAD data of the inspection object 410 and is stored in the three-dimensional CAD data storage unit 330 in advance. The three-dimensional CAD data 510 includes a line segment 511 corresponding to the reference line 411 defined in the inspection object 410. Furthermore, for the three-dimensional CAD data 510, a position 512 where three-dimensional CAD data 520 of the inspection jig 420 is coupled (lines corresponding to a shape of the inspection jig 420, four sides of a rectangle in the example in FIG. 5) is defined.

Furthermore, in FIG. 5, the three-dimensional CAD data 520 is three-dimensional CAD data of the inspection jig 420 and is stored in the three-dimensional CAD data storage unit 330 in advance.

As illustrated in FIG. 5, the coupled three-dimensional CAD data generation unit 301 couples the three-dimensional CAD data 520 of the inspection jig 420 to the three-dimensional CAD data 510 of the inspection object 410 at the position 512. As a result, the coupled three-dimensional CAD data generation unit 301 generates coupled three-dimensional CAD data 121 of a state where the inspection jig 420 is coupled to the inspection object 410. Note that the generated coupled three-dimensional CAD data 121 is stored in the three-dimensional CAD data storage unit 330.

Furthermore, as illustrated in FIG. 5, the line segment identification unit 303 identifies each line segment forming the coupled three-dimensional CAD data 121. In FIG. 5, a table 540 is a table that indicates a start point and an end point of each identified line segment in a three-dimensional space. In the example in FIG. 5, a state where 20 line segments are identified is illustrated based on the coupled three-dimensional CAD data 121.

<Specific Example of Inspection Screen>

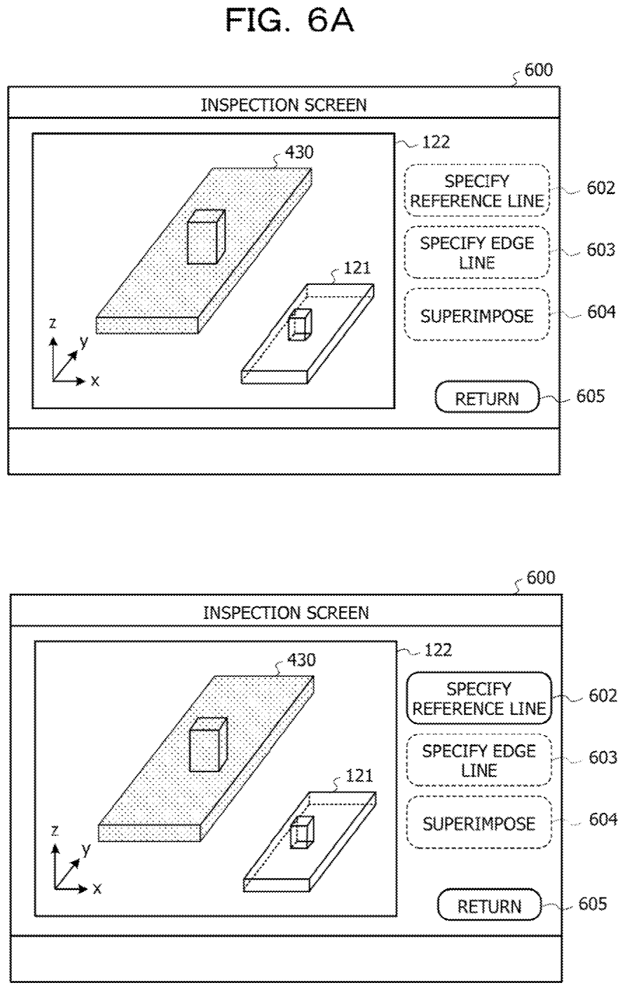

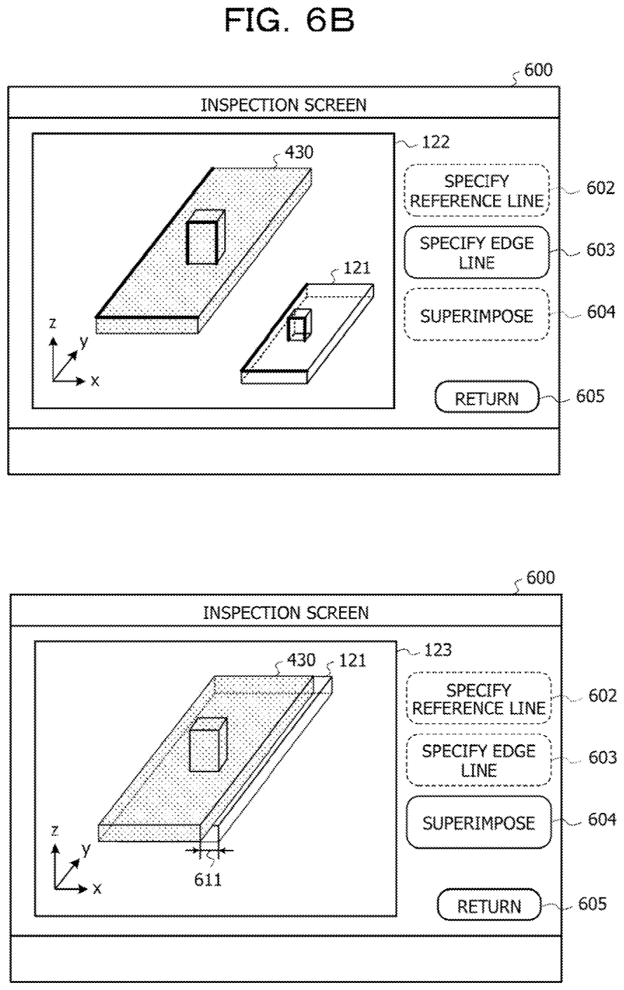

Next, a specific example of an inspection screen in a case where the inspection object 430 is inspected by superimposing and displaying the coupled three-dimensional CAD data 121 on the inspection object 430, to which the inspection jig 420 is coupled, included in the captured image data 122 will be described. FIGS. 6A and 6B are first diagrams and second diagrams illustrating examples of the inspection screen.

Of these, the upper part of FIG. 6A illustrates a state where
the captured image data 122 including the inspection object 430 to which the inspection jig 420 is coupled and
the coupled three-dimensional CAD data 121 corresponding to the inspection object 430

are displayed on an inspection screen 600. Note that the coupled three-dimensional CAD data 121 is displayed to have a posture similar to a posture of the inspection object 430 included in the captured image data 122. At this time, a hidden line of the coupled three-dimensional CAD data 121 is deleted.

Furthermore, the lower part of FIG. 6A illustrates a state where a reference line specification button 602 is pressed and a reference line of the inspection object 430 included in the captured image data 122 and a corresponding line segment in the coupled three-dimensional CAD data 121 are specified on the inspection screen 600.

Furthermore, the upper part of FIG. 6B illustrates a state where an edge line specification button 603 is pressed and a plurality of edge lines of the inspection object 430 included in the captured image data 122 and a plurality of corresponding line segments in the coupled three-dimensional CAD data 121 are specified on the inspection screen 600. Note that in the case of pressing the edge line specification button 603, the inspector 130 is assumed to specify at least three edge lines from edge lines other than the reference line, and specify at least three corresponding line segments.

Moreover, the lower part of FIG. 6B illustrates a state where a superimposition button 604 is pressed and the superimposed data 123 in which the coupled three-dimensional CAD data 121 is superimposed on the inspection object 430 included in the captured image data 122 is displayed on the inspection screen 600.

The example in the lower part of FIG. 6B illustrates that, in the case of the inspection object 430, a dimension in the x axis direction with respect to the reference line is shorter than that in the coupled three-dimensional CAD data 121 by a dimension indicated by reference numeral 611. It is assumed that, in the superimposed data 123, the length of reference numeral 611 is presented as an error calculated in unit of mm, for example.

Note that a return button 605 on each of the inspection screens 600 in FIGS. 6A and 6B is a button for returning the state to a state before an operation performed immediately before the return button 605 is pressed is performed on each of the inspection screens 600.

<Flow of Inspection Processing>

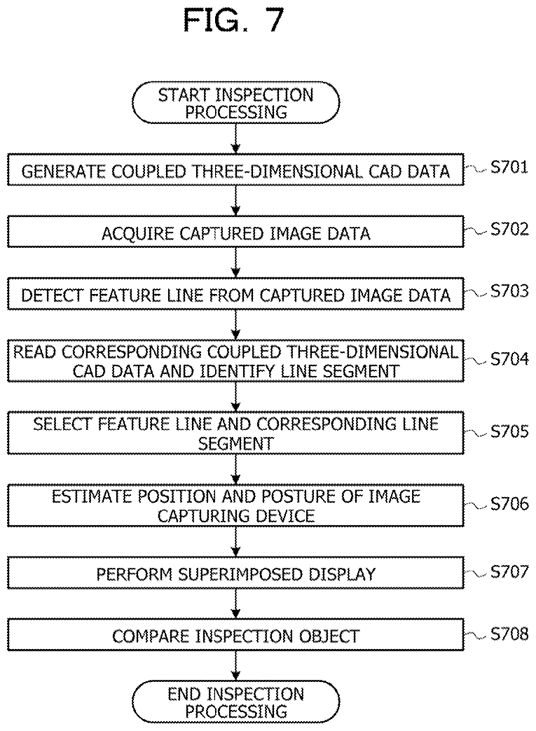

Next, a flow of inspection processing executed by the inspection unit 300 of the information processing apparatus 110 according to the first embodiment will be described. FIG. 7 is a first flowchart illustrating a flow of inspection processing. By activating an inspection program in the information processing apparatus 110, the inspection processing illustrated in FIG. 7 is started.

In step S701, the coupled three-dimensional CAD data generation unit 301 generates coupled three-dimensional CAD data of a state where the inspection jig is coupled to the inspection object and stores the generated data in the three-dimensional CAD data storage unit 330.

In step S702, the captured image data acquisition unit 311 images the inspection object to which the inspection jig is coupled and acquires captured image data. Furthermore, the display unit 323 displays the acquired captured image data on the inspection screen.

In step S703, a feature line detection unit 312 detects a feature line (an edge line) from the acquired captured image data.

In step S704, the coupled three-dimensional CAD data acquisition unit 302 reads coupled three-dimensional CAD data specified by the inspector 130 that is coupled three-dimensional CAD data corresponding to the inspection object included in the captured image data from the three-dimensional CAD data storage unit 330. Furthermore, the display unit 323 displays the read coupled three-dimensional CAD data on the inspection screen. Moreover, the line segment identification unit 303 identifies each line segment forming the read coupled three-dimensional CAD data.

In step S705, when the inspector 130 selects a feature line and a corresponding line segment, the specifying unit 322 receives the selected line and line segment. Specifically, first, the specifying unit 322 receives specification of a reference line in the captured image data. Next, the specifying unit 322 receives specification of a line segment corresponding to the reference line in the coupled three-dimensional CAD data. Next, the specifying unit 322 receives specification of an edge line other than the reference line in the captured image data. Next, the specifying unit 322 receives specification of a line segment corresponding to the edge line other than the reference line in the coupled three-dimensional CAD data.

In step S706, the superimposition unit 321 estimates a position and a posture of the image capturing device 206 when the inspection object to which the inspection jig is coupled is imaged (refer to Reference Documents 1 and 2).
[Reference Document 1] C. Xu et al., “Pose Estimation from Line Correspondences: A Complete Analysis and a Series of Solutions”, IEEE Transactions on Pattern Analysis and Machine Intelligence, Vol. 39, No. 6, pp. 1209-1222, June 2017.
[Reference Document 2] Z. Zhang, “A Flexible New Technique for Camera Calibration”, IEEE Transactions on Pattern Analysis and Machine Intelligence, Vol. 22, No. 11, pp. 1330-1334, November 2000.

In step S707, the superimposition unit 321 scales, moves, or rotates the coupled three-dimensional CAD data based on the estimated position and posture of the image capturing device 206. As a result, the superimposition unit 321 superimposes the coupled three-dimensional CAD data after the scaling, movement, or rotation on the inspection object to which the inspection jig is coupled, the inspection object being included in the captured image data, to generate superimposed data. Furthermore, the display unit 323 displays the generated superimposed data on the inspection screen.

In step S708, the superimposition unit 321 visualizes a deviation amount between the inspection object and the coupled three-dimensional CAD data in the superimposed data and presents the calculated error, and thereafter, terminates the inspection processing.

As is obvious from the above description, the information processing apparatus according to the first embodiment acquires the captured image data including the inspection object to which the jig is coupled, the jig being capable of providing the edge line having a predetermined positional relationship with the reference line of the inspection object. Furthermore, the information processing apparatus according to the first embodiment acquires the coupled three-dimensional CAD data of a state where the jig is coupled to the inspection object. Furthermore, the information processing apparatus according to the first embodiment detects a plurality of edge lines from the acquired captured image data. Moreover, the information processing apparatus according to the first embodiment superimposes and displays the coupled three-dimensional CAD data on the inspection object to which the jig is coupled, the inspection object being included in the captured image data, using the plurality of edge lines detected from the captured image data and the corresponding line segments in the coupled three-dimensional CAD data.

In this way, according to the information processing apparatus according to the first embodiment, it is possible to detect the plurality of edge lines that
are independent of each other and have a sufficient length,
include a reference line predefined in the inspection object, and
are three-dimensionally distributed
   as the appropriate edge lines from the captured image data.

As a result, according to the first embodiment, it is possible to superimpose and display the three-dimensional CAD data on the inspection object included in the captured image data and inspect the inspection object regardless of the imaging environment of the inspection object.

### Second Embodiment

In the above-described first embodiment, a case where the inspection jig has a rectangular parallelepiped shape has been described. However, the shape of the inspection jig is not limited to a rectangular parallelepiped shape and may be a shape suitable for a shape of an inspection object. Hereinafter, in a second embodiment, jigs having various shapes suitable for the shape of the inspection object will be described.

<Example of Inspection Jig Suitable for Two-Hole Inspection Object>

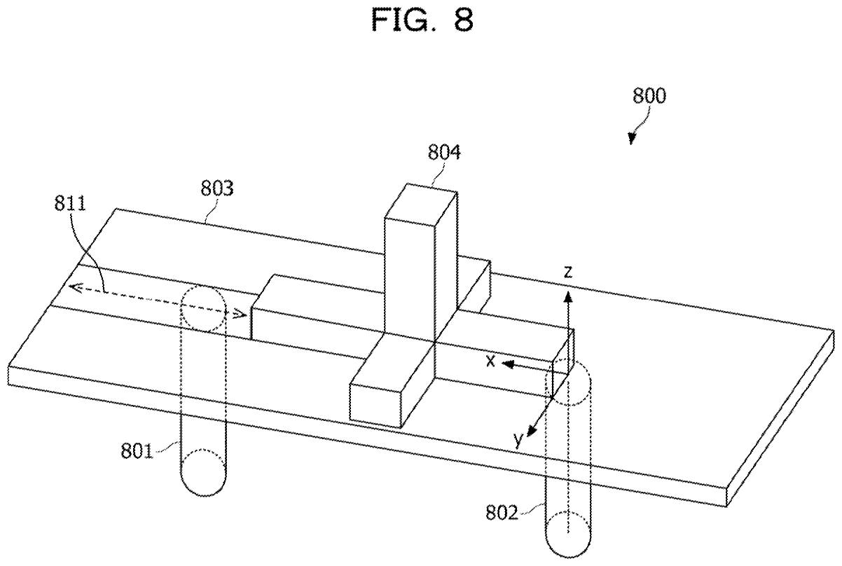

First, an inspection jig suitable for an inspection object in which two machined holes are provided will be described. FIG. 8 is a view illustrating an example of an inspection jig suitable for a two-hole inspection object.

As illustrated in FIG. 8, an inspection jig 800 includes
cylindrical portions 801 and 802 that are respectively fitted into the two machined holes,
a base portion 803 that has a plane substantially orthogonal to the two machined holes in a case where the cylindrical portions 801 and 802 are respectively fitted into the two machined holes, and
a cross portion 804 that can provide an edge line substantially parallel to and an edge line substantially orthogonal to the plane of the base portion 803.

Of these, the cylindrical portion 802 is fixed to the base portion 803. On the other hand, the cylindrical portion 801 is attached to the base portion 803 to be movable in a direction of an arrow 811. As a result, a distance between the cylindrical portion 801 and the cylindrical portion 802 can be changed according to a distance between the two machined holes provided in the inspection object.

Furthermore, the cross portion 804 is formed on the plane of the base portion 803 by combining two rectangular parallelepipeds parallel to the x axis of the x axis, the y axis, and the z axis defined as illustrated in FIG. 8, two rectangular parallelepipeds parallel to the y axis, and a single rectangular parallelepiped parallel to the z axis direction. As a result, it is possible to provide a plurality of edge lines parallel to or orthogonal to each of the x axis, the y axis, and the z axis (as a result, it is possible to provide plurality of edge lines that are three-dimensionally distributed even when being imaged from any direction).

Because machining accuracy of the positions of the machined holes provided in the inspection object is generally high, in the case of an inspection jig 800 in which the cylindrical portions 801 and 802 are respectively fitted into the two machined holes, it is possible to position the cross portion 804 with respect to the reference line with high accuracy.

Note that it is assumed that the plurality of rectangular parallelepipeds forming the cross portion 804 have a sufficient length so as not to interfere with the inspection object when the inspection jig 800 is coupled to the inspection object.

Furthermore, in the example in FIG. 8, although color is not arranged on each surface of the plurality of rectangular parallelepipeds forming the cross portion 804, different colors may be respectively arranged on adjacent surfaces of the plurality of rectangular parallelepipeds (for example, colors having a large difference in luminance from each other). Moreover, when arranging colors, for example, painting may be performed using a paint with a low reflectance.

<Example of Inspection Jig Suitable for One-Hole Inspection Object>

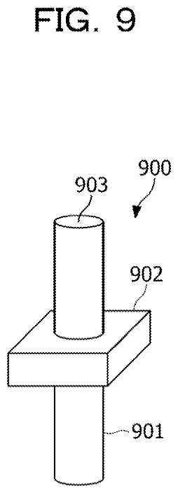

Next, an inspection jig suitable for an inspection object in which a single machined hole is provided will be described. FIG. 9 is a view illustrating an example of an inspection jig suitable for a one-hole inspection object.

As illustrated in FIG. 9, an inspection jig 900 includes
a cylindrical portion 901 fitted into a single machined hole,
a base portion 902 having a plane substantially orthogonal to the single machined hole in a case where the cylindrical portion 901 is fitted into the single machined hole, and
a cylindrical portion 903 substantially orthogonal to the plane of the base portion 902.

Of these, the cylindrical portion 901 is fixed to the base portion 902. Furthermore, in a case where the cylindrical portion 901 is fitted into the single machined hole, the base portion 902 plays a role for avoiding a wobbling movement of the inspection jig 900 with respect to the inspection object.

The cylindrical portion 903 has the same axis as the cylindrical portion 901, and provides two boundary lines (an example of feature lines) when the cylindrical portion 901 is fitted into the single machined hole provided in the inspection object. Note that because the cylindrical portion 903 has a cylindrical shape, two boundary lines (an example of feature lines) are constantly detected at the same interval regardless of an imaging direction around the axis of the machined hole. Therefore, by calculating the center line of the two boundary lines, it is possible to use the center line as the feature line.

Note that, because the machining accuracy of the machined hole provided in the inspection object is generally high, in the case of the inspection jig 900 including the cylindrical portion 903 that has the same axis as the cylindrical portion 901 fitted into the single machined hole, it is possible to position the cylindrical portion 903 with respect to the reference line with high accuracy.

<Example of Inspection Jig Suitable for Non-Hole Inspection Object>

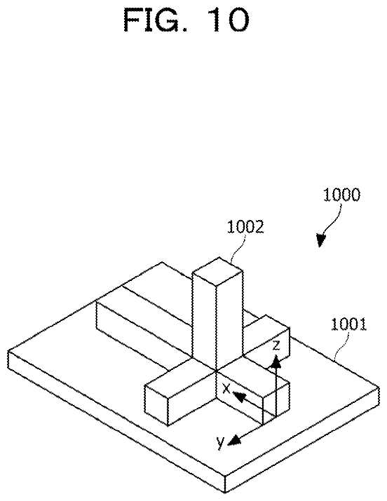

Next, an inspection jig suitable for an inspection object with no machined hole will be described. FIG. 10 is a view illustrating an example of a jig suitable for a non-hole inspection object.

As illustrated in FIG. 10, an inspection jig 1000 includes
a base portion 1001 that is surface-bonded to the inspection object and
a cross portion 1002 that can provide an edge line substantially parallel to and an edge line substantially orthogonal to a plane of the inspection object that is surface-bonded to the base portion 1001.

Of these, a magnet is attached on a rear surface of the base portion 1001 so that the base portion 1001 is surface-bonded to the plane of the inspection object.

Furthermore, the cross portion 1002 is formed on the plane of the base portion 1001 by combining two rectangular parallelepipeds parallel to the x axis of the x axis, the y axis, and the z axis defined as illustrated in FIG. 10, two rectangular parallelepipeds parallel to the y axis, and a single rectangular parallelepiped parallel to the z axis direction. As a result, it is possible to provide the plurality of edge lines parallel to or orthogonal to each of the x axis, the y axis, and the z axis.

Note that it is assumed that the plurality of rectangular parallelepipeds forming the cross portion 1002 have a sufficient length so as not to interfere with the inspection object when the inspection jig 1000 is surface-bonded to the inspection object.

Furthermore, in the example in FIG. 10, although color is not arranged on each surface of the plurality of rectangular parallelepipeds forming the cross portion 1002, different colors may be respectively arranged on adjacent surfaces of the plurality of rectangular parallelepipeds. Moreover, when arranging colors, for example, painting may be performed using a paint with a low reflectance.

Note that, in the case of the inspection jig 1000, it is difficult to position the cross portion 1002 with respect to the reference line of the inspection object with high accuracy. Therefore, in the case of the inspection jig 1000, for example, the inspection jig 1000 is used to inspect a deviation amount of an angle of the inspection object with respect to the coupled three-dimensional CAD data (for example, a deviation amount in a normal direction of the plane of the inspection object).

<Flow of Inspection Processing>

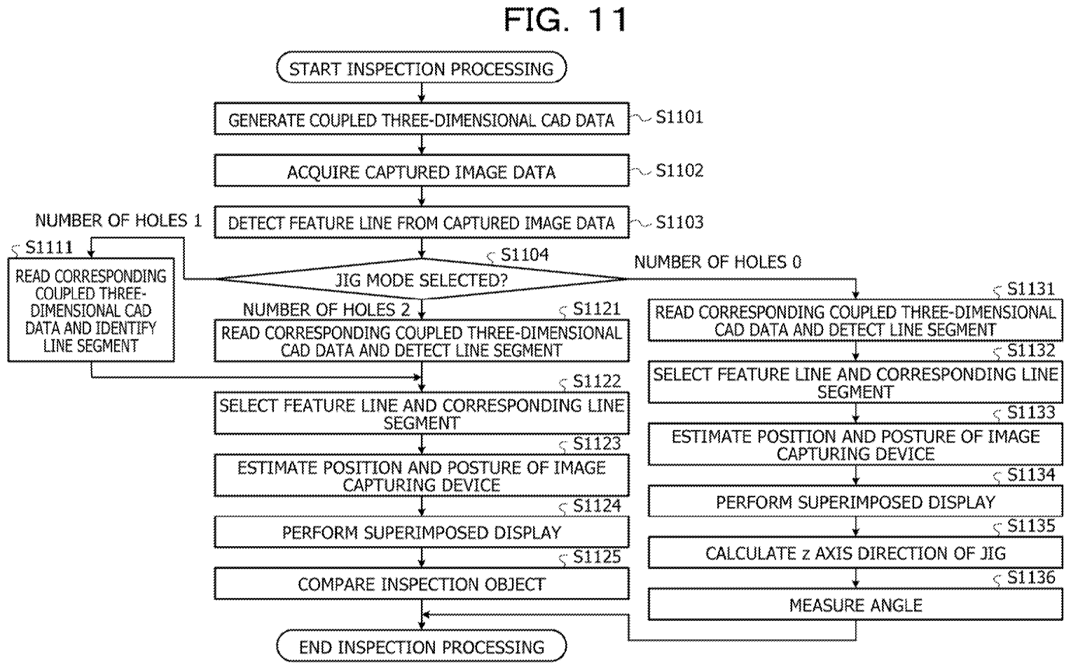

Next, a flow of inspection processing executed by an inspection unit 300 of an information processing apparatus 110 according to the second embodiment will be described. FIG. 11 is a second flowchart illustrating a flow of inspection processing. By activating an inspection program in the information processing apparatus 110, the inspection processing illustrated in FIG. 11 is started.

In step S1101, a coupled three-dimensional CAD data generation unit 301 generates coupled three-dimensional CAD data of a state where the inspection jig is coupled to the inspection object and stores the generated data in a three-dimensional CAD data storage unit 330.

In step S1102, a captured image data acquisition unit 311 images the inspection object to which the inspection jig is coupled and acquires captured image data. Furthermore, a display unit 323 displays the acquired captured image data on an inspection screen.

In step S1103, a feature line detection unit 312 detects a feature line (an edge line or a boundary line) from the acquired captured image data.

In step S1104, in a case where an inspector 130 selects a type of the jig coupled to the inspection object, a coupled three-dimensional CAD data acquisition unit 302 determines which type has been selected in response to the selection. Note that the inspector 130 selects a type of a jig according to the number of machined holes of the inspection object.

In a case where it is determined in step S1104 that a jig coupled to a one-hole inspection object is selected, the procedure proceeds to step S1111.

In step S1111, the coupled three-dimensional CAD data acquisition unit 302 reads coupled three-dimensional CAD data corresponding to the inspection object to which the selected jig (an inspection jig suitable for a one-hole inspection object) is coupled from the three-dimensional CAD data storage unit 330. Furthermore, a display unit 323 displays the read coupled three-dimensional CAD data on an inspection screen. Moreover, a line segment identification unit 303 identifies a line segment forming the read coupled three-dimensional CAD data.

On the other hand, in a case where it is determined in step S1104 that a jig coupled to a two-hole inspection object is selected, the procedure proceeds to step S1121.

In step S1121, the coupled three-dimensional CAD data acquisition unit 302 reads coupled three-dimensional CAD data corresponding to the inspection object to which the selected jig (an inspection jig suitable for a two-hole inspection object) is coupled from the three-dimensional CAD data storage unit 330. Furthermore, a display unit 323 displays the read coupled three-dimensional CAD data on an inspection screen. Moreover, the line segment identification unit 303 identifies a line segment forming the read coupled three-dimensional CAD data.

In step S1122, when the inspector 130 selects a feature line and a corresponding line segment, the specifying unit 322 receives the selected line and line segment. Specifically, first, the specifying unit 322 receives specification of a reference line in the captured image data. Next, the specifying unit 322 receives specification of a line segment corresponding to the reference line in the coupled three-dimensional CAD data. Furthermore, the specifying unit 322 receives specification of an edge line or a boundary line other than the reference line in the captured image data. Moreover, the specifying unit 322 receives specification of a line segment corresponding to the edge line or the boundary line other than the reference line in the coupled three-dimensional CAD data.

In step S1123, a superimposition unit 321 estimates a position and a posture of an image capturing device 206 when the inspection object to which the inspection jig is coupled is imaged.

In step S1124, the superimposition unit 321 scales, moves, or rotates the coupled three-dimensional CAD data based on the estimated position and posture of the image capturing device 206. As a result, the superimposition unit 321 superimposes the coupled three-dimensional CAD data after the scaling, movement, or rotation on the inspection object (the inspection object coupled to the inspection jig suitable for a one-hole or two-hole inspection object) included in the captured image data to generate superimposed data. Furthermore, the display unit 323 displays the generated superimposed data on the inspection screen.

In step S1125, the superimposition unit 321 visualizes a deviation amount between the coupled three-dimensional CAD data and the inspection object in the superimposed data and presents the calculated error.

On the other hand, in a case where it is determined in step S1104 that the inspection jig coupled to the non-hole inspection object is selected, the procedure proceeds to step S1131.

In step S1131, the coupled three-dimensional CAD data acquisition unit 302 reads coupled three-dimensional CAD data corresponding to the inspection object coupled to the selected jig (an inspection jig suitable for a non-hole inspection object) from the three-dimensional CAD data storage unit 330. Furthermore, a display unit 323 displays the read coupled three-dimensional CAD data on an inspection screen. Moreover, the line segment identification unit 303 identifies a line segment forming the read coupled three-dimensional CAD data.

In step S1132, when the inspector 130 selects a feature line and a corresponding line segment, the specifying unit 322 receives the selected line and line segment. Specifically, first, the specifying unit 322 receives specification of a reference line in the captured image data. Furthermore, the specifying unit 322 receives specification of a line segment corresponding to the reference line in the coupled three-dimensional CAD data. Furthermore, the specifying unit 322 receives specification of an edge line other than the reference line in the captured image data. Moreover, the specifying unit 322 receives specification of a line segment corresponding to the edge line other than the reference line in the coupled three-dimensional CAD data.

In step S1133, the superimposition unit 321 estimates a position and a posture of the image capturing device 206 when the inspection object to which the inspection jig is coupled is imaged.

In step S1134, the superimposition unit 321 scales, moves, or rotates the coupled three-dimensional CAD data based on the estimated position and posture of the image capturing device 206. As a result, the superimposition unit 321 superimposes the coupled three-dimensional CAD data after the scaling, movement, or rotation on the inspection object (the inspection object coupled to the inspection jig suitable for a non-hole inspection object) included in the captured image data to generate superimposed data. Furthermore, the display unit 323 displays the generated superimposed data on the inspection screen.

In step S1135, the superimposition unit 321 calculates an angle of the edge line other than the reference line, of which the specification is received in step S1132, in the z axis direction (a normal direction of a plane in surface-contact with the inspection jig suitable for a non-hole inspection object).

In step S1136, the superimposition unit 321 visualizes a deviation amount between the coupled three-dimensional CAD data and the inspection object (a deviation amount of an angle in the z axis direction of the edge line) in the superimposed data and presents the calculated error of the angle.

As is obvious from the above description, in the second embodiment, the plurality of jigs having the shapes suitable for the shape of the inspection object is prepared and is properly used according to the shape of the inspection object. As a result, according to the information processing apparatus according to the second embodiment, the plurality of appropriate feature lines can be detected regardless of the shape of the inspection object.

As a result, according to the second embodiment, it is possible to superimpose and display the three-dimensional CAD data on the inspection object included in the captured image data and inspect the inspection object regardless of the shape of the inspection object.

### Third Embodiment

In the above-described first embodiment, the description has been made while assuming that the inspector 130 presses the reference line specification button 602, the edge line specification button 603, or the like, and then specifies the reference line, the edge line other than the reference line, and the corresponding line segments. However, the method of specifying the reference line by the inspector 130 is not limited to this. For example, first, the plurality of edge lines and corresponding line segments may be specified, and a pair of the reference line and the corresponding line segment may be specified from among pairs of the plurality of specified edge lines and the corresponding line segments.

Furthermore, in the above-described first embodiment, the description has been made while assuming that the inspector 130 specifies the line segment corresponding to the edge line other than the reference line. However, the inspector 130 may specify the edge line other than the reference line of the inspection object included in the captured image data 122, and the specifying unit 322 may automatically associate the corresponding line segment with the edge line other than the reference line of the coupled three-dimensional CAD data 121. Alternatively, the edge line other than the reference line and the corresponding line segment may be automatically selected, for example, by the superimposition unit 321 respectively from the coupled three-dimensional CAD data 121 and the captured image data 122 and may be associated with each other.

Furthermore, in the above-described first and second embodiments, the description has been made while assuming that the inspector 130 specifies the reference line of the inspection object included in the captured image data 122 and the line segment corresponding to the reference line in the coupled three-dimensional CAD data 121 so as to associate the reference line with the line segment. However, the inspector 130 may specify the reference line of the inspection object included in the captured image data 122, and may not specify the line segment corresponding to the reference line of the coupled three-dimensional CAD data 121. That is, the specifying unit 322 may automatically perform association (pairing) on the line segment corresponding to the reference line in the coupled three-dimensional CAD data 121 based on the specified reference line of the inspection object. In this case, the specifying unit 322 functions as a pairing unit.

Furthermore, in the above-described first and second embodiments, the description has been made while assuming that the coupled three-dimensional CAD data 121 is scaled, moved, or rotated and superimposition is performed on the coupled three-dimensional CAD data 121 so that the reference line is matched at the time of superimposition and display. However, at the time of superimposition and display, the reference line does not need to be completely matched. For example, the coupled three-dimensional CAD data 121 may be scaled, moved, or rotated so that a degree of coincidence between the reference lines is equal to or more than a predetermined degree of coincidence, and superimposition is performed on the coupled three-dimensional CAD data 121.

Furthermore, in the above-described first and the second embodiments, the description has been made while assuming that the superimposed display is performed such that the reference line is matched. However, superimposed display may be performed such that a reference point is matched.

Furthermore, in the above-described first and second embodiments, the description has been made while assuming that the coupled three-dimensional CAD data is generated before the captured image data is acquired.

However, the coupled three-dimensional CAD data may be generated after the captured image data is acquired.

### Fourth Embodiment

In the above-described first embodiment, the description has been made while assuming that, in superimposing and displaying the coupled three-dimensional CAD data on the inspection object to which the inspection jigs included in the captured image data is coupled, the inspector 130 specifies the reference line, the edge line other than the reference line, the corresponding line segment, and the like. In contrast, in a fourth embodiment, an operation load on an inspector 130 when performing superimposed display is decreased by reducing items specified by the inspector 130. Hereinafter, the fourth embodiment will be described focusing on differences from each of the above-described embodiments.

<Description of Inspection Jig>

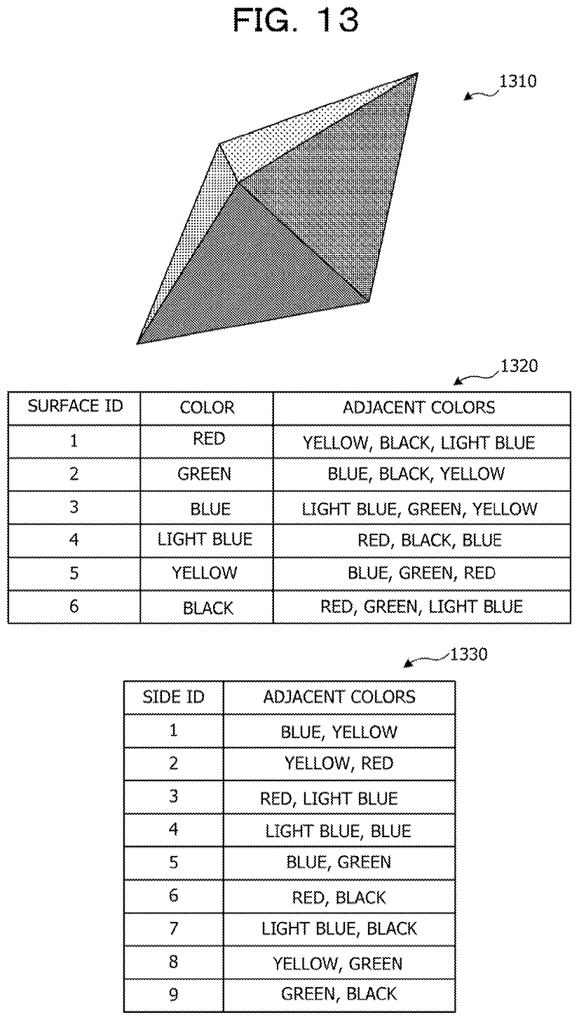

First, an inspection jig used when an information processing apparatus according to the fourth embodiment executes inspection processing will be described. FIG. 13 is a view and tables illustrating an example of a shape of the inspection jig and color arrangement data of the jig.

As illustrated in FIG. 13, a jig 1310 has a shape of a triangular dipyramid, and colors (six colors) different from one another are arranged on respective surfaces (six surfaces). By forming the jig 1310 with a dipyramid such as a triangular dipyramid, even if the jig 1310 is imaged from an arbitrary position, a feature line detection unit can detect, from captured image data,
edge lines that are independent of each other and have a sufficient length, and
edge lines three-dimensionally distributed with each other.

Furthermore, by arranging colors different from one another on the respective surfaces of the triangular dipyramid, a color region extraction unit, which will be described below, can extract surfaces in two or more different types of colors from the captured image data even in the case where the jig 1310 is imaged from an arbitrary position.

Note that, as in the above-described first embodiment, in the case where the shape of the jig is a rectangular parallelepiped, even if colors different from one another are arranged on the respective surfaces, the color region extraction unit to be described below is not able to extract surfaces in two or more different types of colors from the captured image data in a case of capturing an image from the front. In this case, it is not possible to distinguish top and bottom and right and left of the rectangular parallelepiped. In contrast, in the case of the jig 1310, even if an image is captured from an arbitrary position, the color region extraction unit to be described below can extract the surfaces in two or more different types of colors, and thus can distinguish the top and bottom and right and left.

Note that, in FIG. 13, table 1320 is a table illustrating color arrangement data indicating the color arranged on each surface of the jig 1310 and the colors arranged on the adjacent surfaces, and includes “surface ID”, “color”, and “adjacent colors” as items of information.

An identifier for identifying each surface of the jig 1310 is stored in the “surface ID”. As described above, the jig 1310 is formed with a triangular dipyramid and has six surfaces, so “1” to “6” are stored in the “surface ID”.

The color arranged on each surface of the jig 1310 is stored in the “color”. The example of FIG. 13 illustrates that the color arranged on each surface is “red” color, “green” color, “blue” color, “light blue” color, “yellow” color, or “black” color.

The colors arranged on the surfaces adjacent to the surface identified by the corresponding “surface ID” are arranged and stored in counterclockwise order in the “adjacent colors”. In the case of a triangular dipyramid, the shape of each surface is a triangle and each surface is adjacent to three surfaces. Therefore, three types of colors are arranged and stored in the “adjacent colors”.

Furthermore, in FIG. 13, table 1330 is a table illustrating color arrangement data indicating the colors arranged on the surfaces adjacent to each side of the jig 1310, and includes “side ID” and “adjacent colors” as items of information.

An identifier for identifying each side of the jig 1310 is stored in the “side ID”. Since the jig 1310 has nine sides, “1” to “9” are stored in the “side ID”.

The colors arranged on the two surfaces adjacent to the side identified by the corresponding “side ID” are stored in the “adjacent colors”.

<Functional Configuration of Information Processing Apparatus>

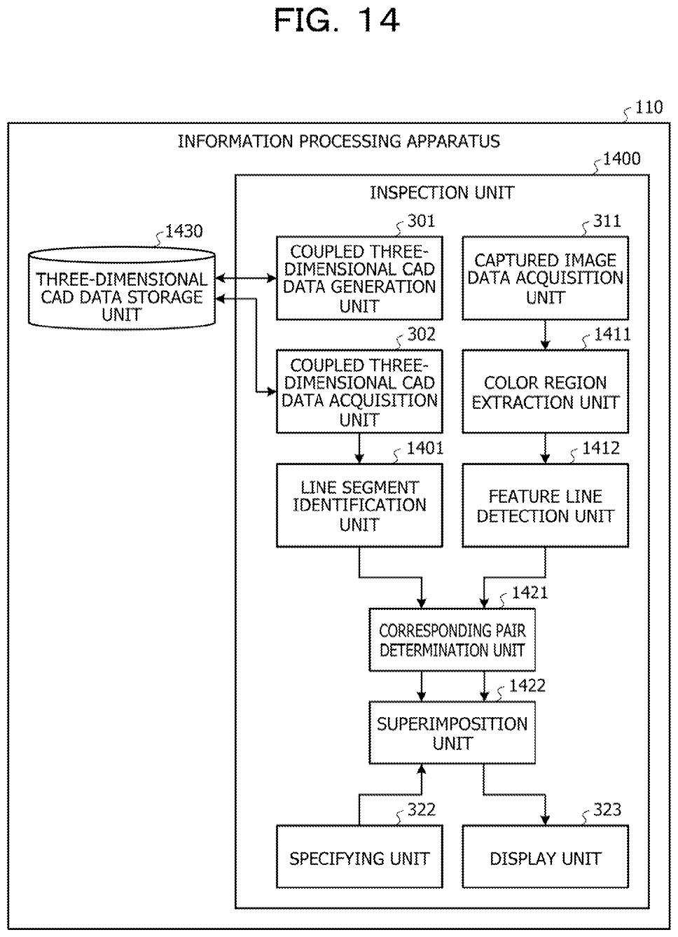

Next, a functional configuration of an information processing apparatus according to the fourth embodiment will be described. FIG. 14 is a second diagram illustrating an example of the functional configuration of the information processing apparatus. The difference from the functional configuration described with reference to FIG. 3 in the above-described first embodiment is that a color region extraction unit 1411 and a corresponding pair determination unit 1421 are provided in the case of FIG. 14. Furthermore, in the case of FIG. 14, functions of a line segment identification unit 1401, a feature line detection unit 1412, and a superimposition unit 1422 are different from the functions of the line segment identification unit 303, the feature line detection unit 312, and the superimposition unit 321, respectively. Moreover, in the case of FIG. 14, three-dimensional CAD data and coupled three-dimensional CAD data stored in a three-dimensional CAD data storage unit 1430 are different from the three-dimensional CAD data and the coupled three-dimensional CAD data stored in the three-dimensional CAD data storage unit 330. Details of the differences will be described below.

The line segment identification unit 1401 identifies each line segment in read coupled three-dimensional CAD data. Note that the line segment identification unit 1401 identifies the line segment of each side of the jig 1310 in the coupled three-dimensional CAD data. At this time, the line segment identification unit 1401 acquires the colors arranged on the two surfaces adjacent to each identified line segment. Furthermore, the line segment identification unit 1401 notifies the corresponding pair determination unit 1421 of each identified line segment and the colors arranged on the two surfaces adjacent to the each identified line segment.

The color region extraction unit 1411 extracts a color region from captured image data 122. Specifically, the color region extraction unit 1411 extracts a region in which the color of each surface of the inspection jig 1310 is arranged, included in the captured image data. Furthermore, the color region extraction unit 1411 notifies the feature line detection unit 1412 of the extracted color region.

The feature line detection unit 1412 extracts a contour side of each color region notified from the color region extraction unit 1411, and identifies a boundary line of each color of the triangular dipyramid and adjacent colors adjacent to the boundary line of each color. Note that, in the present embodiment, the contour side refers to a side of a polygonal contour formed by each color region in the captured image data 122.

Furthermore, the feature line detection unit 1412 extracts edge lines from the captured image data 122 and associates each extracted edge line with the boundary line of each color, thereby specifying adjacent colors adjacent to each edge line. Moreover, the feature line detection unit 1412 notifies the corresponding pair determination unit 1421 of each edge line and the adjacent colors adjacent to each edge line.

The corresponding pair determination unit 1421 specifies a corresponding pair of the line segment and the edge line based on
each line segment and the colors arranged on the two surfaces adjacent to each line segment notified by the line segment identification unit 1401, and
each edge line and the adjacent colors adjacent to each edge line notified by the feature line detection unit 1412.

The superimposition unit 1422 estimates the position and posture of the image capturing device 206 based on the corresponding pair specified by the corresponding pair determination unit 1421.

By estimating the position and posture of the image capturing device 206, the superimposition unit 321 scales, moves, or rotates the coupled three-dimensional CAD data 121 and automatically superimposes the coupled three-dimensional CAD data 121 on the captured image data 122 to generate superimposed data 123.

As described above, according to the information processing apparatus 110 according to the fourth embodiment, the inspector 130 does not need to specify
the reference line and the edge line other than the reference line, and
the corresponding line segment, and the like
   in superimposing and displaying the coupled three-dimensional CAD data on the inspection object to which the inspection jig included in the captured image data 122 is coupled. As a result, according to the information processing apparatus 110 according to the fourth embodiment, it is possible to reduce an operation load of the inspector 130 when superimposed display is performed.

Note that, in the case of the information processing apparatus 110 according to the fourth embodiment, the reference line is not specified and thus superimposed display is performed such that the edge line of the jig 1310 matches the corresponding line segment, instead of performing superimposed display such that the reference line matches the corresponding line segment. Therefore, according to the fourth embodiment, the inspector 130 grasps a deviation amount and a cause of the deviation by comparing the edge line other than the edge line of the jig 1310 (that is, the edge line of an inspection object 1510) with the corresponding line segment. That is, in the fourth embodiment, the edge line of the jig 1310 serves as a reference line.

<Coupling Example in a Case where Inspection Jig is Coupled to Inspection Object and Edge Line Detection Example>

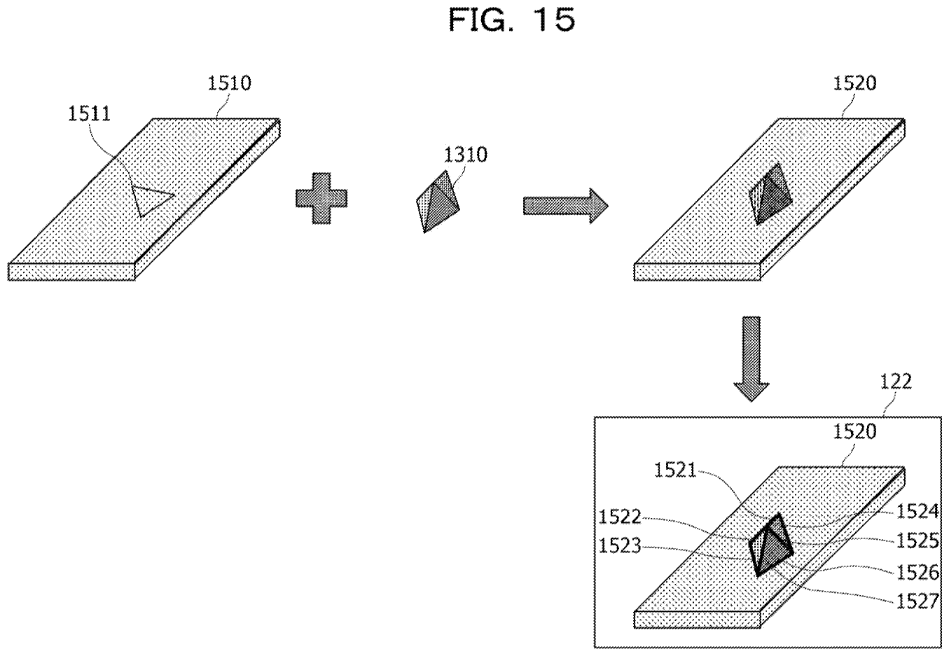

Next, a coupling example in a case where the inspection jig 1310 is coupled to the inspection object and a detection example of an edge line detected from the captured image data including the inspection object to which the inspection jig 1310 is coupled will be described. FIG. 15 is a diagram illustrating a coupling example in the case where the inspection jig is coupled to the inspection object and an edge line detection example.

As illustrated in FIG. 15, for an inspection object 1510, a manufacturer defines a position 1511 at which an inspection jig 1310 is coupled (lines corresponding to a shape of the inspection jig 1310, three sides of a triangle in the example of FIG. 15).

Furthermore, as illustrated in FIG. 15, the inspection jig 1310 has a shape of a triangular dipyramid, and provides, as described above,
the edge lines that are independent of each other and have a sufficient length, and
the edge lines three-dimensionally distributed with each other in the case of being coupled to the inspection object 1510.

Furthermore, as illustrated in FIG. 15, when an inspection object 1520 after the inspection jig 1310 is coupled at the position 1511 is captured by the image capturing device 206, the captured image data acquisition unit 311 acquires the captured image data 122.

Note that the example of FIG. 15 illustrates seven edge lines 1521 to 1527 (an example of feature lines) are detected in the captured image data 122.

<Specific Example of Coupled Three-Dimensional CAD Data and Identification Example of Line Segment>

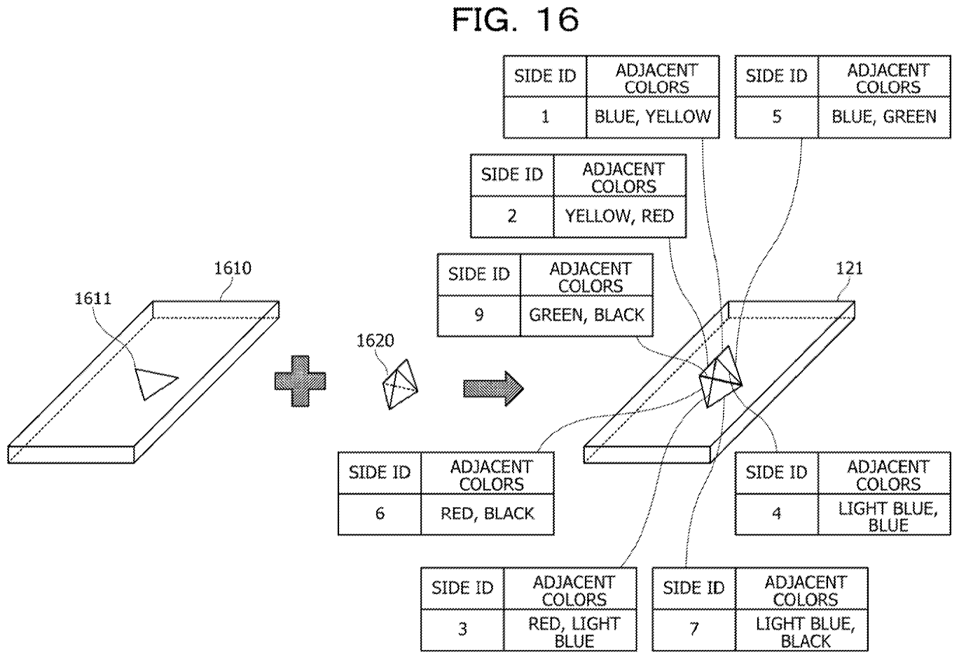

Next, a specific example of the coupled three-dimensional CAD data and an identification example of a line segment forming the coupled three-dimensional CAD data will be described. FIG. 16 is a second diagram illustrating a specific example of the coupled three-dimensional CAD data and an identification example of line segments.

In FIG. 16, three-dimensional CAD data 1610 is three-dimensional CAD data of the inspection object 1510 and is stored in the three-dimensional CAD data storage unit 1430 in advance. For the three-dimensional CAD data 1610, a position 1611 at which three-dimensional CAD data 1620 of the inspection jig 1310 is coupled (lines corresponding to a shape of the inspection jig 1310, three sides of a triangle in the example of FIG. 16) is defined.

Furthermore, in FIG. 16, the three-dimensional CAD data 1620 is three-dimensional CAD data of the inspection jig 1310 and is stored in the three-dimensional CAD data storage unit 1430 in advance.

As illustrated in FIG. 16, the coupled three-dimensional CAD data generation unit 301 couples the three-dimensional CAD data 1610 of the inspection jig 1310 to the three-dimensional CAD data 1610 of the inspection object 1510 at the position 1611. Therefore, the coupled three-dimensional CAD data generation unit 301 generates the coupled three-dimensional CAD data 121 in the state where the inspection jig 1310 is coupled to the inspection object 1510. Note that the generated coupled three-dimensional CAD data 121 is stored in the three-dimensional CAD data storage unit 1430.

Furthermore, as illustrated in FIG. 16, the line segment identification unit 1401 identifies each line segment forming the coupled three-dimensional CAD data 121. In FIG. 16, the information extracted from each line segment by the lead line represents the side ID for identifying each line segment identified by the line segment identification unit 1401 and information indicating the adjacent colors of each line segment.

<Specific Example of Corresponding Pair Determination Processing>

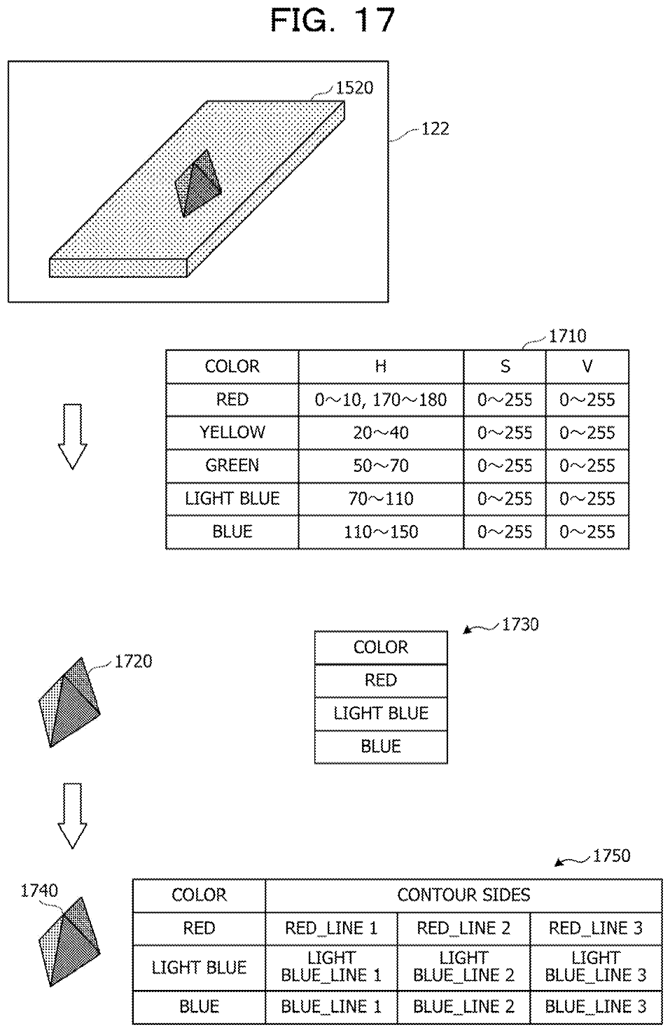

Next, a specific example of corresponding pair determination processing by the color region extraction unit 1411, the feature line detection unit 1412, and the corresponding pair determination unit 1421 will be described. FIGS. 17 to 19 are first to third diagrams illustrating a specific example of the corresponding pair determination processing.

As described above, when the captured image data 122 is notified by the captured image data acquisition unit 311, the color region extraction unit 1411 extracts the color region (the region where the color of each surface of the inspection jig 1310 is arranged) included in the captured image data 122. Note that the color region extraction unit 1411 converts, for example, pixel values (R value, G value, and B value) of each pixel of the captured image data 122 into HSV values, and compares the converted pixel values with table 1710. Therefore, the color region extraction unit 1411 identifies the color of each pixel of the captured image data 122, and extracts a cluster of pixels of each color as each color region.

In FIG. 17, reference numeral 1730 represents the color area extracted from the captured image data 122, and reference numeral 1720 represents the color of the extracted color region.

Furthermore, as described above, the feature line detection unit 1412 extracts the contour sides from each color region (reference numeral 1720) notified by the color region extraction unit 1411. Reference numeral 1740 represents the contour sides extracted from each color region (reference numeral 1720), and reference numeral 1750 represents details of the extracted contour sides.

As represented by reference numeral 1750, three contour sides are extracted from each of red, light blue, and blue regions. Note that any method can be used to extract the contour sides but the feature line detection unit 1412 extracts the contour sides according to the following procedure, for example.
A binary image in which the red region is white and regions other than the red region are black, a binary image in which the light blue region is white and regions other than the light blue region are black, and a binary image in which the blue region is white and regions other than the blue region are black are respectively generated.
In each binary image, the black and white boundary pixels are connected to extract the contour side according to, for example, Non-Patent Document A below.
[Non-Patent Document A] S. Suzuki et al., “Topological structural analysis of digitized binary images by border following”, Computer Vision, Graphics and Image Processing, 30 (1985): pp. 32-46
   The extracted contour sides are approximated to the shape of each surface of a dipyramid (in the present embodiment, it is a triangular dipyramid, so a triangle) according to, for example, Non-Patent Document B below.
[Non-Patent Document B] D. Douglas et al., “Algorithms for the reduction of the number of points required for represent a digitized line or its caricature”, Canadian Cartographer, 10 (1973): pp. 112-122

Next, the feature line detection unit 1412 specifies the boundary line of each color region and the adjacent colors adjacent to the boundary line of each color. Specifically, the feature line detection unit 1412 first calculates coordinates of a start point and coordinates of an end point in the captured image data 122 of each contour side included in reference numeral 1750. Next, the feature line detection unit 1412 determines contour sides that match each other among the contour sides included in reference numeral 1750. Specifically, the feature line detection unit 1412 determines that two contour sides match in a case of satisfying both of the conditions:
an angle formed by one contour side and the other contour side is within a predetermined angle, and
a distance between the start point of one contour side and the start point of the other contour side, or a distance between the end point of one contour side and the end point of the other contour side, whichever is shorter, is a predetermined distance.

Then, in the case of determining that the two contour sides match, the feature line detection unit 1412 registers the contour sides as the boundary line of corresponding adjacent colors, and registers the coordinates of the start point and the coordinates of the end point of the boundary line in the captured image data 122.

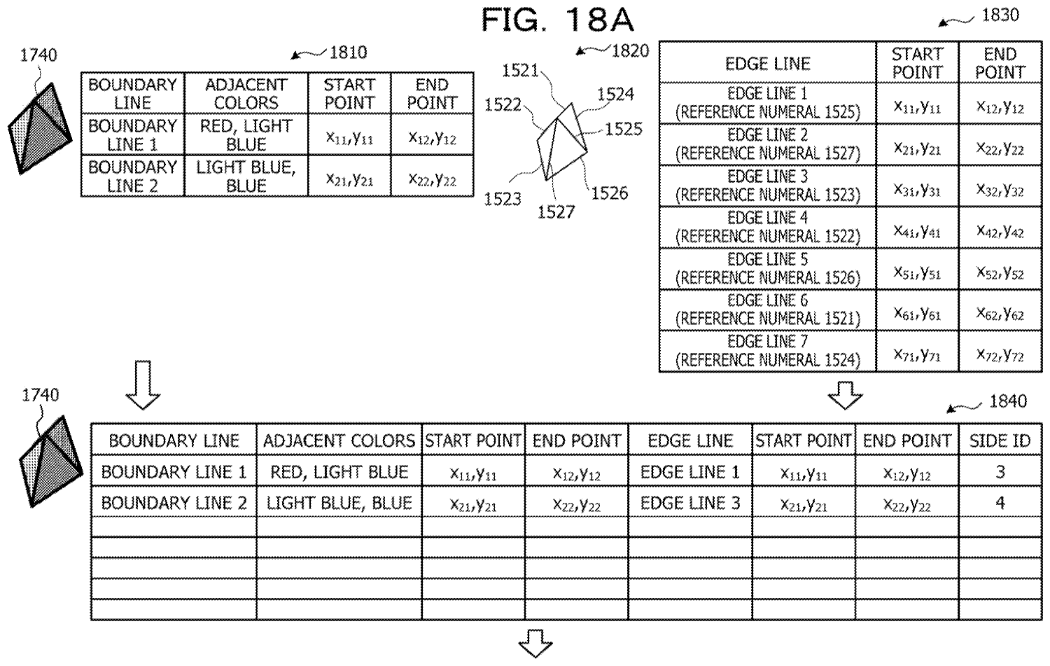

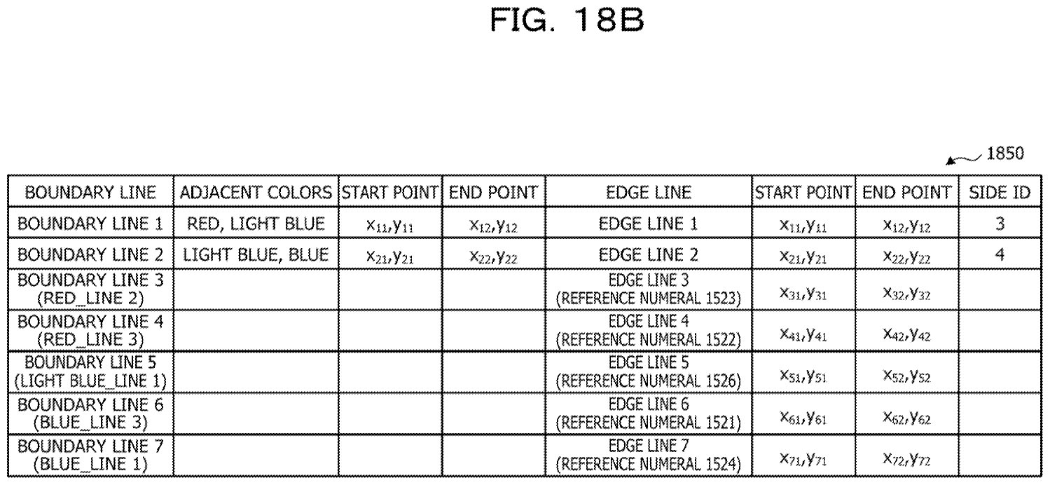

Reference numeral 1810 in FIG. 18A indicates a state where red_line 1 and light blue_line 2 out of the nine contour sides included in reference numeral 1750 are determined to match, and are registered as “boundary line 1” of adjacent colors (red and light blue). Furthermore, a state where light blue_line 3 and blue_line 2 match, and are registered as “boundary line 2” of adjacent colors (light blue and blue) is illustrated.

Meanwhile, reference numeral 1820 in FIG. 18A represents edge lines 1521 to 1527 detected from the captured image data 122 by the feature line detection unit 1412. Furthermore, reference numeral 1830 in FIG. 18A represents coordinates within the captured image data 122, of start points and end points of the seven detected edge lines 1521 to 1527.

The feature line detection unit 1412 selects the edge line closest to each boundary line indicated by reference numeral 1810 from the table indicated by reference numeral 1830 and matches the lines. Any matching method can be used by the feature line detection unit 1412. For example, a slope and an intercept of the boundary line and a slope and an intercept of the edge line are parameterized, respectively, and the edge line with the closest slope and intercept is selected.

Reference numeral 1840 in FIG. 18A indicates a state where “edge line 1” is selected as the edge line closest to “boundary line 1” and “edge line 2” is selected as the edge line closest to “boundary line 2”. Therefore, the adjacent colors of “edge line 1” and “edge line 2” are specified, so the corresponding pair determination unit 1421 specifies the side ID (that is, the line segment of the coupled three-dimensional CAD data) of the jig 1310 by referring to table 1330 (FIG. 13) (see reference numeral 1840).

Note that, as described in the first embodiment, in principle, four pairs of line segments and edge lines are needed for superimposed display. Therefore, the feature line detection unit 1412 and the corresponding pair determination unit 1421 also match the edge lines with other contour sides and specify the adjacent colors to specify the side IDs.

Specifically, the feature line detection unit 1412 extracts the contour sides whose adjacent colors are not specified from among the contour sides indicated by reference numeral 1740, and searches for the edge lines corresponding to the respective contour sides (the edge lines other than the matched edge lines, of the edge lines of reference numeral 1830).

In the case of FIG. 18A, “red_line 2”, “red_line 3”, “light blue_line 1”, “blue_line 1”, and “blue_line 3” are extracted as the contour sides whose adjacent colors are not specified, and corresponding edge lines are searched from “edge line 3” to “edge line 7”.

As described above, “edge line 1” and “edge line 2” have already been matched with the contour sides and the side IDs have been specified. For this reason, it is sufficient to specify the side IDs by matching the contour sides with the remaining two edge lines, but here, a case of matching all the five edge lines with the contour sides to specify the side IDs will be described. Note that, it is assumed that, in a case of matching only two edge lines of the five edge lines with the contour sides to specify the side IDs, for example, only the top two edge lines with the longest length are matched with the contour sides and the side IDs are specified.

Reference numeral 1850 in FIG. 18B indicates a state where the edge lines to match the extracted contour sides “red_line 2”, “red_line 3”, “light blue_line 1”, “blue_line 3”, and “blue_line 1” are searched from “edge line 3” to “edge line 7”.

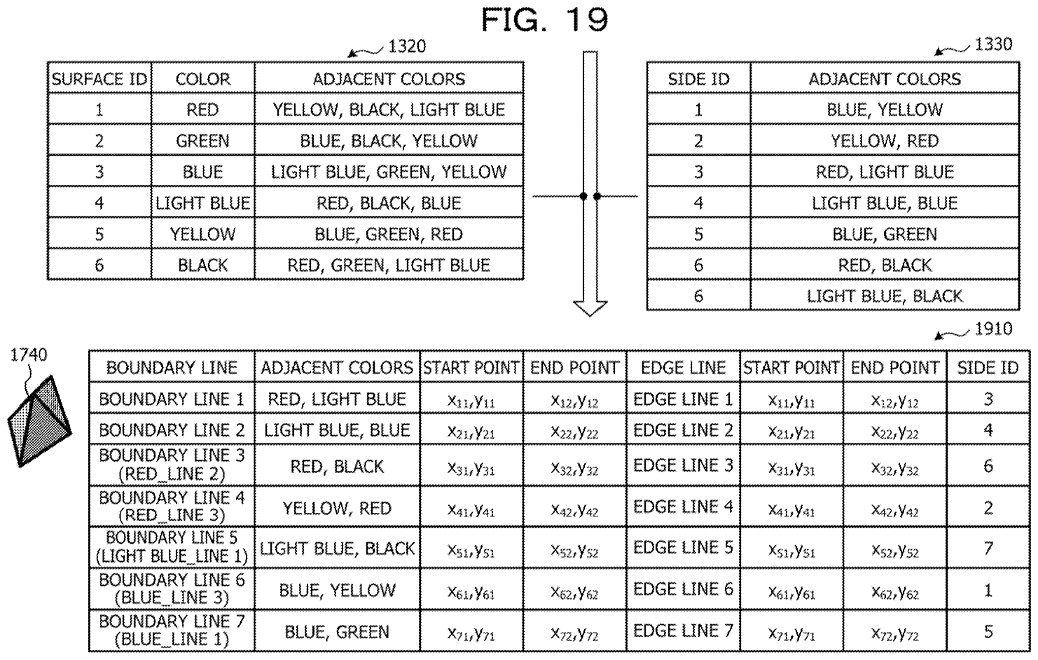

Next, as illustrated in FIG. 19, the corresponding pair determination unit 1421 specifies the side IDs corresponding to “edge line 3” to “edge line 7”. Here, regarding each of “boundary line 3” to “boundary line 7” (“red_line 2” to “blue_line 1”) matched with “edge line 3” to “edge line 7”, one of two adjacent surfaces is visible and the other is invisible.

Therefore, the corresponding pair determination unit 1421 refers to table 1320 (FIG. 13) and specifies the color of the invisible surface. For example, “boundary line 3” and “boundary line 4” are the contour sides of the red surface. Meanwhile, according to table 1320, the colors of the surfaces adjacent to the red surface are yellow, black, and light blue, counterclockwise. Here, according to reference numeral 1740 in FIG. 19, among the surfaces adjacent to the red surface, the light blue surface is visible. Therefore, the invisible surfaces are the yellow surface and the black surface, and by going counterclockwise, the invisible surface adjacent to “boundary line 3” can be specified as black. Furthermore, the invisible surface adjacent to “boundary line 4” can be specified as yellow.

That is, the adjacent colors of “boundary line 3 (red_line 2)” can be specified as red and black, and the adjacent colors of “boundary line 4 (red_line 3)” can be specified as yellow and red. Therefore, the corresponding pair determination unit 1421 can specify the side ID of “edge line 3” as “6” and the side ID of “edge line 4” as “2” by referring to table 1330 (see reference numeral 1910).

Similarly, “boundary line 5 (light blue_line 1)” is the contour side of the light blue surface, and according to table 1320, the colors of the surfaces adjacent to the light blue surface are red, black, and blue, counterclockwise. Here, according to reference numeral 1740 in FIG. 19, among the surfaces adjacent to the light blue surface, the blue surface and the red surface are visible. Therefore, the invisible surface is the black surface, and the invisible surface adjacent to “boundary line 5 (light blue_line 1)” can be specified as black.

That is, the adjacent colors of “boundary line 5 (light blue_line 1)” can be specified as light blue and black. Therefore, the corresponding pair determination unit 1421 can specify the side ID of “edge line 5” as “7” by referring to table 1330 (see reference numeral 1910).

Similarly, “boundary line 6 (blue_line 3)” and “boundary line 7 (blue_line 1)” are the contour side of the blue surface, and according to table 1320, the colors of the surfaces adjacent to the blue surface are light blue, green, and yellow, counterclockwise. Here, according to reference numeral 1740 in FIG. 19, among the surfaces adjacent to the blue surface, the light blue surface is visible. Therefore, the invisible surfaces are the green surface and the yellow surface, and by going counterclockwise, the invisible surface adjacent to “boundary line 7” can be specified as green. Furthermore, the invisible surface adjacent to “boundary line 6” can be specified as yellow.

That is, the adjacent colors of “boundary line 6 (blue_line 3)” can be specified as blue and yellow, and the adjacent colors of “boundary line 7 (blue_line 1)” can be specified as blue and green. Therefore, the corresponding pair determination unit 1421 can specify the side ID of “edge line 6” as “1” and the side ID of “edge line 7” as “5” by referring to table 1330 (see reference numeral 1910).

<Specific Example of Inspection Screen>

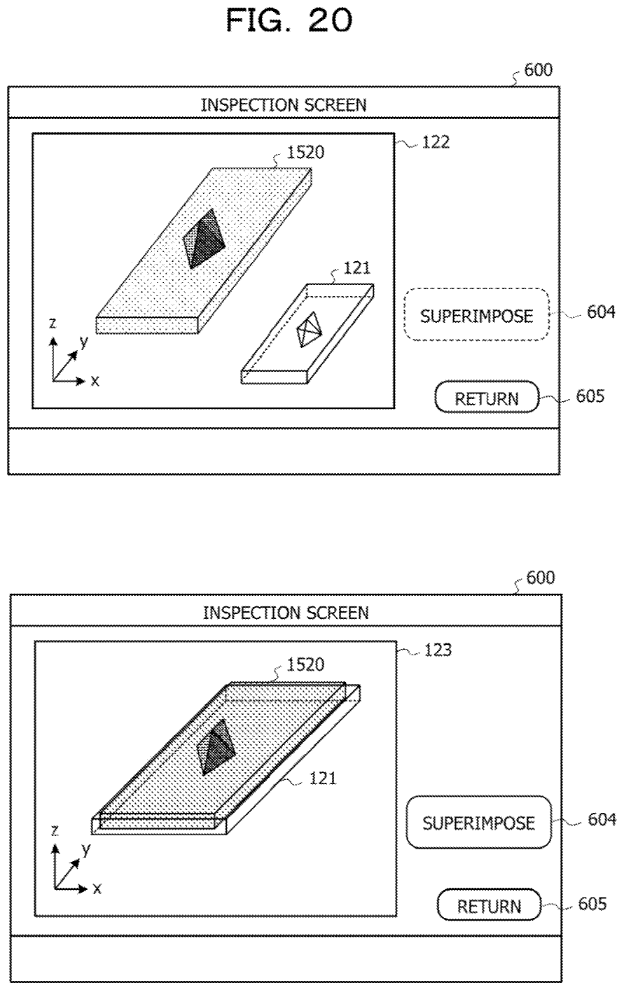

Next, a specific example of an inspection screen in the information processing apparatus 110 according to the fourth embodiment will be described. FIG. 20 is third diagrams illustrating examples of the inspection screen.

In FIG. 20, the upper part illustrates a state where
the captured image data 122 including the inspection object 1520 to which the inspection jig 1310 is coupled and
the coupled three-dimensional CAD data 121 that is the coupled three-dimensional CAD data corresponding to the inspection object 1520 are displayed on the inspection screen 600.

Moreover, the lower part of FIG. 20 illustrates a state where a superimposition button 604 is pressed and the superimposed data 123 in which the coupled three-dimensional CAD data 121 is superimposed on the inspection object 1520 included in the captured image data 122 is displayed on the inspection screen 600.

As described above, while in the above-described first embodiment, the inspector 130 needs to specify the reference line, the edge lines other than the reference line, the corresponding line segments, and the like in displaying the superimposed data 123, the fourth embodiment only needs pressing of the superimposition button 604. That is, according to the fourth embodiment, it is possible to reduce the operation load on the inspector 130 when performing superimposed display.

<Flow of Inspection Processing>

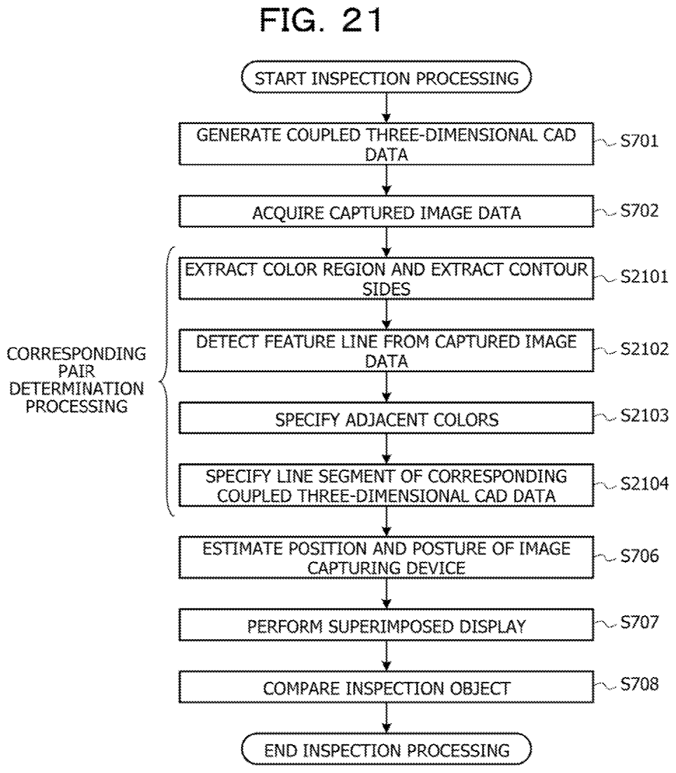

Next, a flow of inspection processing executed by an inspection unit 1400 of the information processing apparatus 110 according to the fourth embodiment will be described. FIG. 21 is a second flowchart illustrating a flow of the inspection processing. By activating an inspection program in the information processing apparatus 110, the inspection processing illustrated in FIG. 21 is started.

Note that a difference from the first flowchart illustrated in FIG. 7 is corresponding pair determination processing in steps S2101 to S2104.

In step S2101, the color region extraction unit 1411 extracts the color region from the acquired captured image data, and extracts the contour side of each color region.

In step S2102, the feature line detection unit 1412 detects a feature line (edge line) from the acquired captured image data.

In step S2103, the feature line detection unit 1412 searches the detected feature lines (edge lines) for the feature line (edge line) corresponding to the extracted contour side. Furthermore, the corresponding pair determination unit 1421 specifies the colors of the surfaces adjacent to the contour side for which the feature line (edge line) has been searched.

In step S2104, the corresponding pair determination unit 1421 specifies each line segment of the coupled three-dimensional CAD data corresponding to each feature line (edge line) based on the adjacent colors.

As is clear from the above description, in the fourth embodiment, as information for identifying the line segment in the three-dimensional CAD data of the jig, color information of each of two surfaces adjacent to the line segment is associated. Furthermore, in the fourth embodiment, the colors of the two surfaces adjacent to the edge line detected from the captured image data are specified, and the coupled three-dimensional CAD data is superimposed and displayed based on the line segment associated with the color information matching the specified adjacent colors and the edge line.

As a result, according to the fourth embodiment, it is possible to obtain similar effects to the above-described first embodiment, and to reduce the operation load on the inspector 130 when performing superimposed display.

### Other Embodiments

In the above-described fourth embodiment, the case where different colors (that is, six colors) are arranged on the respective surfaces of the jig 1310 has been described. Meanwhile, since one of the six surfaces of the jig 1310 is attached to the inspection object 1510, the color of that surface may be the same as the colors of the other five surfaces. That is, the surfaces of the jig 1310 may be colored with six colors or less.

Note that the present invention is not limited to the configurations described here, and may include combinations of the configurations or the like described in the above-described embodiments with other elements, and the like. These points can be changed without departing from the spirit of the present invention, and can be appropriately determined according to application modes of the points.

The present application claims the benefit of priority based on Japanese Patent Application No. 2020-128279, filed on Jul. 29, 2020, which is incorporated by reference herein in its entirety.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable storage medium storing an inspection program that causes at least one computer to execute a process, the process comprising:
acquiring a captured image that includes an inspection object to which a jig that provides a feature line that has a certain positional relationship with the inspection object is coupled;
acquiring a three-dimensional image in a state where the jig is coupled to the inspection object;
detecting a plurality of feature lines from the captured image; and
displaying the three-dimensional image superimposed on the inspection object which is included in the captured image and to which the jig is coupled, by using the plurality of feature lines detected from the captured image and line segments of the three-dimensional image which correspond to the plurality of feature lines.

2. The non-transitory computer-readable storage medium according to claim 1, wherein the process further comprising
generating the three-dimensional image of a state where the jig is coupled to the inspection object based on a three-dimensional image of the inspection object and a three-dimensional image of the jig.

3. The non-transitory computer-readable storage medium according to claim 1, wherein
the displaying includes displaying the three-dimensional image so that a reference line that is a specified feature line among the plurality of feature lines detected from the captured image matches the corresponding line segment of the three-dimensional image, and the feature line other than the reference line among the plurality of feature lines detected from the captured image matches the corresponding line segment of the three-dimensional image.

4. The non-transitory computer-readable storage medium according to claim 3, wherein
the displaying includes visualizing a deviation amount between the inspection object which is included in the captured image and to which the jig is coupled, and the three-dimensional image.

5. The non-transitory computer-readable storage medium according to claim 3, wherein
the displaying includes visualizing a deviation amount of an angle between the feature line other than the reference line among the plurality of feature lines detected from the captured image and the corresponding line segment of the three-dimensional image.

6. The non-transitory computer-readable storage medium according to claim 2, wherein the process further comprising
associating information that identifies a line segment of a three-dimensional image of a jig with color information of each of two surfaces adjacent to the line segment, wherein
when two surfaces adjacent to the feature line detected from the captured image are included in the captured image, the displaying includes displaying the three-dimensional image based on the feature line detected from the captured image, and a line segment associated with color information that matches the color information of each of the two adjacent surfaces.

7. The non-transitory computer-readable storage medium according to claim 6, wherein the process further comprising
associating information that identifies a surface of a three-dimensional image of a jig with color information of each of three surfaces adjacent to the surface in a certain order, wherein
when one surface of the two surfaces adjacent to the feature line detected from the captured image is not included in the captured image, the detecting includes specifying the color information of the one surface by acquiring the color information of each of three surfaces adjacent to the other surface included in the captured image, and the displaying includes displaying the three-dimensional image based on the feature line detected from the captured image, and a line segment associated with color information that matches the color information of the other surface and the specified color information of the one surface.

8. The non-transitory computer-readable storage medium according to claim 6, wherein the jig is a dipyramid, and each surface of the jig is formed with a triangle.

9. The non-transitory computer-readable storage medium according to claim 8, wherein the jig is a triangular dipyramid, and surfaces of the jig are colored with six colors or less.

10. An information processing apparatus comprising:
one or more memories; and
one or more processors coupled to the one or more memories and the one or more processors configured to:
acquire a captured image that includes an inspection object to which a jig that provides a feature line that has a certain positional relationship with the inspection object is coupled,
acquire a three-dimensional image in a state where the jig is coupled to the inspection object,
detect a plurality of feature lines from the captured image, and
display the three-dimensional image superimposed on the inspection object which is included in the captured image and to which the jig is coupled, by using the plurality of feature lines detected from the captured image and line segments of the three-dimensional image which correspond to the plurality of feature lines.

11. The information processing apparatus according to claim 10, wherein the one or more processors are further configured to
generate the three-dimensional image of a state where the jig is coupled to the inspection object based on a three-dimensional image of the inspection object and a three-dimensional image of the jig.

12. The information processing apparatus according to claim 10, wherein the one or more processors are further configured to
display the three-dimensional image so that a reference line that is a specified feature line among the plurality of feature lines detected from the captured image matches the corresponding line segment of the three-dimensional image, and the feature line other than the reference line among the plurality of feature lines detected from the captured image matches the corresponding line segment of the three-dimensional image.

13. The information processing apparatus according to claim 12, wherein the one or more processors are further configured to
visualize a deviation amount between the inspection object which is included in the captured image and to which the jig is coupled, and the three-dimensional image.

14. The information processing apparatus according to claim 12, wherein the one or more processors are further configured to
visualize a deviation amount of an angle between the feature line other than the reference line among the plurality of feature lines detected from the captured image and the corresponding line segment of the three-dimensional image.

15. An inspection method for a computer to execute a process comprising:
acquiring a captured image that includes an inspection object to which a jig that provides a feature line that has a certain positional relationship with the inspection object is coupled;
acquiring a three-dimensional image in a state where the jig is coupled to the inspection object;
detecting a plurality of feature lines from the captured image; and
displaying the three-dimensional image superimposed on the inspection object which is included in the captured image and to which the jig is coupled, by using the plurality of feature lines detected from the captured image and line segments of the three-dimensional image which correspond to the plurality of feature lines.

16. The inspection method according to claim 15, wherein the process further comprising
generating the three-dimensional image of a state where the jig is coupled to the inspection object based on a three-dimensional image of the inspection object and a three-dimensional image of the jig.

17. The inspection method according to claim 15, wherein
the displaying includes displaying the three-dimensional image so that a reference line that is a specified feature line among the plurality of feature lines detected from the captured image matches the corresponding line segment of the three-dimensional image, and the feature line other than the reference line among the plurality of feature lines detected from the captured image matches the corresponding line segment of the three-dimensional image.

18. The inspection method according to claim 17, wherein
the displaying includes visualizing a deviation amount between the inspection object which is included in the captured image and to which the jig is coupled, and the three-dimensional image.

19. The inspection method according to claim 17, wherein
the displaying includes visualizing a deviation amount of an angle between the feature line other than the reference line among the plurality of feature lines detected from the captured image and the corresponding line segment of the three-dimensional image.
